(19) United States
(12) Patent Application Publication
(10) Pub. No.: US 2023/0257883 A1
(43) Pub. Date: Aug. 17, 2023

(54) SUBSTRATE PROCESSING APPARATUS, RECORDING MEDIUM, AND METHOD OF MANUFACTURING SEMICONDUCTOR DEVICE

(71) Applicant: Kokusai Electric Corporation, Tokyo (JP)

(72) Inventors: Hideto YAMAGUCHI, Toyama-shi (JP); Seiya Shigematsu, Toyama-shi (JP); Masaaki Ueno, Toyama-shi (JP); Masashi Sugishita, Toyama-shi (JP); Shuhei Maeda, Toyama-shi (JP); Tetsuya Kosugi, Toyama-shi (JP)

(73) Assignee: Kokusai Electric Corporation, Tokyo (JP)

(21) Appl. No.: 18/188,879

(22) Filed: Mar. 23, 2023

Related U.S. Application Data
(63) Continuation of application No. PCT/JP2020/037162, filed on Sep. 30, 2020.

(51) Int. Cl. C23C 16/46; H01L 21/477

(52) U.S. Cl. CPC C23C 16/46; H01L 21/477

(57) ABSTRACT

There is provided a technique that includes: a reaction tube where a process chamber configured to process a substrate is formed; a heater structure including a heater heating the substrate; a cooler including a cooling valve supplying a cooling medium; an exhaust fan supplying the cooling medium to the cooler; and a cooling controller configured to: acquire a prediction model that includes information of the exhaust fan, final target temperature, and opening state of the cooling valve and estimates a predicted temperature predicting at least one selected from the group of a temperature of the heater and a temperature of the process chamber; acquire the at least one selected from the group of the temperature of the heater and the temperature of the process chamber, the opening state of the cooling valve, and the information of the exhaust fan; and regulate the opening state of the cooling valve.

### CROSS-REFERENCE TO RELATED APPLICATION

This application is a Bypass Continuation Application of PCT International Application No. PCT/JP2020/037162, filed Sep. 30, 2020, the disclosure of which is incorporated herein in its entirety by reference.

### TECHNICAL FIELD

The present disclosure relates to a substrate processing apparatus, a recording medium, and a method of manufacturing a semiconductor device.

### BACKGROUND

It is known that an example of a substrate processing apparatus is a semiconductor manufacturing apparatus and an example of the semiconductor manufacturing apparatus is a vertical apparatus. In the vertical apparatus, a boat as a substrate holder that holds a plurality of substrates (hereinafter also referred to as wafers) in multiple stages is loaded into a process chamber inside a reaction tube while holding the substrates, and the substrates are processed at a predetermined temperature while performing temperature control in a plurality of zones. So far, in the related art, when a temperature of a heater is controlled, the heater is turned off while the temperature is being lowered. However, in recent years, attempts are made to actively improve temperature lowering characteristics after substrate processing.

For example, in the related art, a semiconductor manufacturing apparatus is disclosed in which heating by a heater unit and cooling by a cooling unit are performed in parallel to follow a predetermined temperature increase rate and a predetermined temperature decrease rate. Further, in the related art, a semiconductor manufacturing apparatus is disclosed in which temperature characteristics are automatically acquired in advance and is then used to control the temperature to prevent variations in control performance due to coordinators.

Here, when a flow rate of a cooling gas is controlled in the cooling unit configuration described above, during rapid cooling, a change in temperature decrease rate for each zone may differ, causing a difference in temperature history among the zones. Further, in feedback control by PID operation, an appropriate parameter may be determined in advance, but an optimization of this PID parameter may take a procedure of searching for an optimum value through trial and error, and the result thereof is highly dependent on intuition and experience of the coordinators.

### SUMMARY

The present disclosure provides a technique capable of improving a temperature deviation among zones by using optimum parameters.

According to some embodiments of the present disclosure, there is provided a technique that includes: a reaction tube in which a process chamber configured to process a substrate is formed; a heater structure that is installed outside the reaction tube and includes a heater configured to heat the substrate; a cooler including a cooling valve configured to supply a cooling medium to a space between the heater structure and the reaction tube; an exhaust fan configured to supply the cooling medium to the cooler; and a cooling controller configured to: acquire a prediction model that includes information of the exhaust fan, a final target temperature that is a future target, and an opening state of the cooling valve and estimates a predicted temperature that predicts at least one selected from the group of a temperature of the heater and a temperature of the process chamber; acquire the at least one selected from the group of the temperature of the heater and the temperature of the process chamber, the opening state of the cooling valve, and the information of the exhaust fan; and regulate the opening state of the cooling valve to minimize an error between a predicted temperature column calculated according to the prediction model and a target temperature column calculated from a rate of change from a present target temperature to the final target temperature when the change occurs.

### BRIEF DESCRIPTION OF DRAWINGS

The accompanying drawings, which are incorporated in and constitute a portion of the specification, illustrate embodiments of the present disclosure.

FIG. 1 is a partial cross-sectional front view showing a substrate processing apparatus according to some embodiments of the present disclosure.

FIG. 2 is a cross-sectional front view of a substrate processing apparatus according to some embodiments of the present disclosure.

FIG. 3 is a view that explains a temperature controller according to some embodiments of the present disclosure.

FIG. 4 is a diagram showing a hardware structure of a computer in a substrate processing apparatus according to some embodiments of the present disclosure.

FIG. 5 is an internal control block diagram of a cooling controller according to some embodiments of the present disclosure.

FIG. 6 is a flowchart that explains a first effective constraint method used in the present disclosure.

FIG. 7 is a flowchart that explains a second effective constraint method used in the present disclosure.

FIG. 8 is an internal control block diagram of a cooling controller according to other embodiments of the present disclosure.

FIG. 9 is an internal control block diagram of the cooling controller when generating a rapid cooling prediction model of the present disclosure.

FIG. 10 is a control block diagram showing an example of an automatic acquisition process of a rapid cooling prediction model of the present disclosure.

FIG. 11 is a flowchart showing an example of a temperature-related process in a film-forming process according to some embodiments of the present disclosure.

FIG. 12 is a diagram showing an in-furnace temperature change in the flowchart shown in FIG. 11.

FIG. 13 is a view that explains operations of a controller 200, a temperature controller 64, and a cooling controller 300 in the flowchart shown in FIG. 11.

FIG. 14A is a diagram showing an in-furnace temperature of each zone and an inter-zone temperature deviation when a temperature control is performed by using a cooling controller according to a comparative example. FIG. 14B is a diagram showing an in-furnace temperature of each zone and an inter-zone temperature deviation when a temperature control is performed by using a cooling controller according to the embodiments of the present disclosure.

FIG. 15A is a diagram showing an actual measured value of an in-furnace temperature, a predicted temperature, and an error therebetween when a temperature control is performed without using information of an exhaust fan in a cooling controller according to the embodiments of the present disclosure. FIG. 15B is a diagram showing an actual measured value of an in-furnace temperature, a predicted temperature, and an error therebetween when a temperature control is performed by using a cooling controller according to the embodiments of the present disclosure.

### DETAILED DESCRIPTION

Reference will now be made in detail to various embodiments, examples of which are illustrated in the accompanying drawings. In the following detailed description, numerous specific details are set forth to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

### <Embodiments of the Present Disclosure>

Some embodiments of the present disclosure will now be described with reference to the drawings. The drawings used in the following description are schematic, and dimensional relationships, ratios, and the like of various components shown in figures may not match actual ones. Further, dimensional relationships, ratios, and the like of various components among plural figures may not match one another.

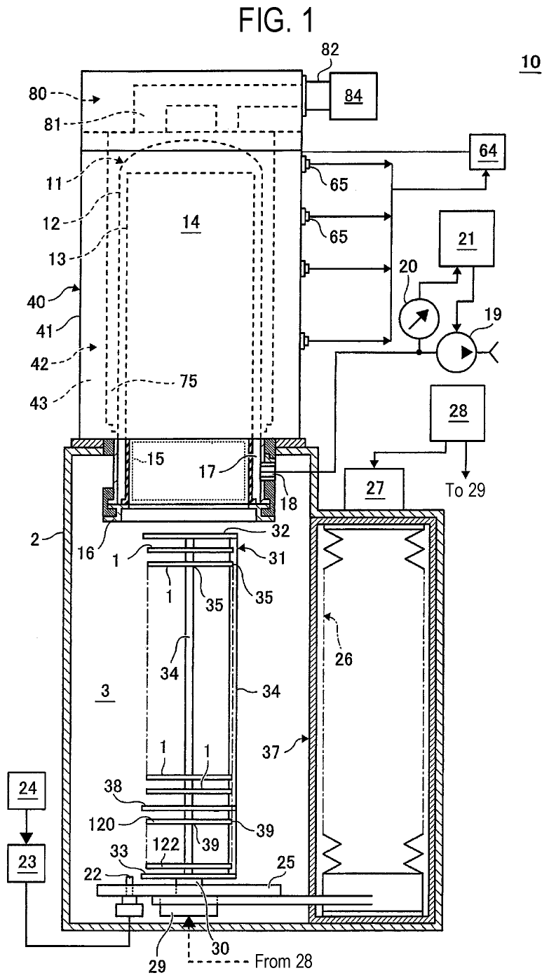

In the embodiments of the present disclosure, as shown in FIGS. 1 to 3, a substrate processing apparatus 10 according to the present disclosure is constituted as a processing apparatus 10 configured to perform processing steps in a method of manufacturing a semiconductor device.

The substrate processing apparatus 10 shown in FIG. 1 includes a process tube 11 as a supported vertical reaction tube, and the process tube 11 includes an outer tube 12 and an inner tube 13 which are arranged to be concentric with each other. The outer tube 12 is made of quartz (SiO₂) and is integrally formed in a cylindrical shape with its upper end closed and its lower end opened. The inner tube 13 is formed in a cylindrical shape with both upper and lower ends opened. An interior of a cylindrical hollow area of the inner tube 13 forms a process chamber 14 into which a boat to be described later is loaded, and a lower end opening of the inner tube 13 constitutes a furnace opening 15 via which the boat is loaded or unloaded. As will be described later, the boat 31 is configured to hold a plurality of wafers as substrates such that the wafers are aligned in a long array. Therefore, an inner diameter of the inner tube 13 is set to be larger than a maximum outer diameter (for example, 300 mm in diameter) of the wafer 1 to be handled.

A lower end side between the outer tube 12 and the inner tube 13 is hermetically sealed by a manifold 16 constructed in substantially a cylindrical shape. The manifold 16 is installed such that the manifold 16 may be attached to or detached from the outer tube 12 and the inner tube 13 respectively for replacement of the outer tube 12 and the inner tube 13. The process tube 11 is vertically installed by supporting the manifold 16 on a housing 2 of a CVD apparatus. Hereinafter, in some cases, the outer tube 12 may be shown as the process tube 11 in the drawings.

A gap between the outer tube 12 and the inner tube 13 forms an exhaust passage 17 in a circular ring shape with a constant width in cross section. As shown in FIG. 1, one end of an exhaust pipe 18 is connected to an upper side of a sidewall of the manifold 16, and the exhaust pipe 18 communicates with the lowest end of the exhaust passage 17. An exhaust apparatus 19 controlled by a pressure controller 21 is connected to the other end of the exhaust pipe 18, and a pressure sensor 20 is connected in the middle of the exhaust pipe 18. The pressure controller 21 is configured to feedback-control the exhaust apparatus 19 based on a measurement result from the pressure sensor 20.

A gas introduction pipe 22 is disposed below the manifold 16 such that the gas introduction pipe 22 communicates with the furnace opening 15 of the inner tube 13, and a precursor gas supplier and an inert gas supplier (hereinafter, referred to as a gas supplier) 23 are connected to the gas introduction pipe 22. The gas supplier 23 is configured to be controlled by a gas flow rate controller 24. A gas introduced into the furnace opening 15 via the gas introduction pipe 22 flows through the process chamber 14 of the inner tube 13 and is exhausted from the exhaust pipe 18 via the exhaust passage 17.

A seal cap 25 configured to close a lower end opening of the manifold 16 is in contact with the manifold 16 from below in the vertical direction. The seal cap 25 is constructed in a disc shape with substantially the same outer diameter as the manifold 16 and is configured to be lifted vertically by a boat elevator 26 installed at a waiting room 3 of the housing 2. The boat elevator 26 includes a motor-driven feed screw shaft apparatus, bellows, etc., and a motor 27 of the boat elevator 26 is configured to be controlled by a drive controller 28. A rotary shaft 30 is arranged and rotatably supported on the center line of the seal cap 25 and is configured to be rotated by a rotator 29 as a motor, which is controlled by the drive controller 28. The boat 31 is vertically supported on the upper end of the rotary shaft 30.

The boat 31 includes a pair of upper and lower end plates 32 and 33 and three holders 34 vertically installed between the upper and lower end plates 32 and 33, and a large number of holding grooves 35 are engraved in the three holders 34 at an equal interval in the longitudinal direction. The holding grooves 35 engraved in the same stage in the three holders 34 are opened to face each other. By inserting a wafer 1 among the holding grooves 35 of the same stage of the three holders 34, the boat 31 holds a plurality of wafers 1 horizontally and with their centers aligned with another. A heat insulation cap 36 is arranged between the boat 31 and the rotary shaft 30. The rotary shaft 30 supports the boat 31 while lifting the boat 31 from the upper surface of the seal cap 25 such that the lower end of the boat 31 is separated by an appropriate distance from a position of the furnace opening 15. The heat insulation cap 36 is designed to insulate the vicinity of the furnace opening 15.

A heater structure 40 as a vertically-arranged heater is concentrically arranged outside the process tube 11 and is installed in a state of being supported by the housing 2. The heater structure 40 includes a case 41. The case 41 is made of stainless steel (SUS) and is formed in a tubular shape, specifically a cylindrical shape, with its upper end closed and its lower end opened. The inner diameter and overall length of the case 41 are set to be larger than the outer diameter and overall length of the outer tube 12. In the embodiments of the present disclosure, the heater structure 40 is divided into seven control zones U1, U2, CU, C, CL, L1, and L2, as a plurality of control zones, from the upper end to the lower end of the heater structure 40.

A heat insulation structure 42 is installed inside the case 41. The heat insulation structure 42 according to the embodiments of the present disclosure is formed in a tubular shape, specifically a shape of a cylinder, and a sidewall 43 of the cylinder is formed in a multi-layer structure. Further, the heat insulation structure 42 includes a partition 105 that vertically separates the sidewall 43 into a plurality of zones (regions), and a heat generator 56 that is installed inside the sidewall 43 and serves as a heater configured to heat the wafer 1 in the process chamber 14.

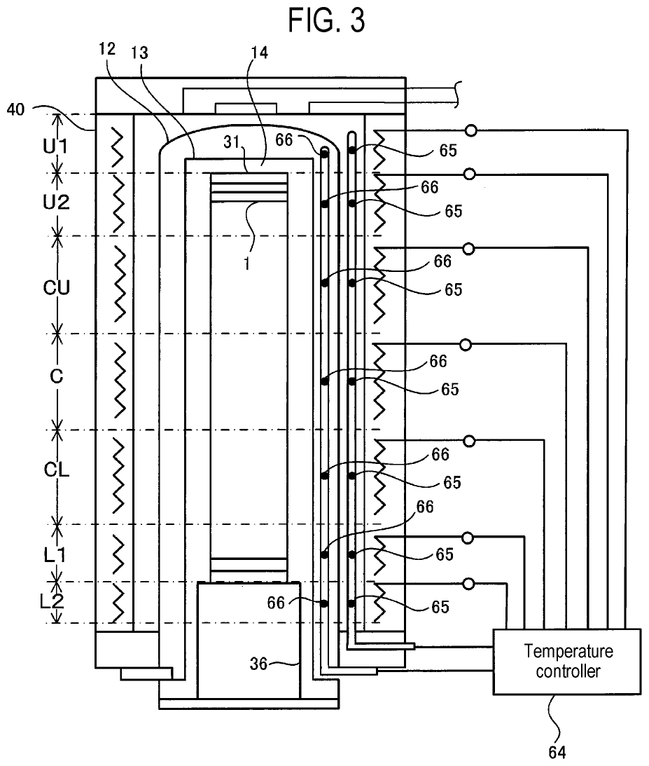

The heater structure 40 is configured to be controlled by a temperature controller 64, as shown in FIG. 3. The heater structure 40 is also provided with a pair of thermocouple 65 and thermocouple 66 corresponding to each of the control zones U1, U2, CU, C, CL, L1, and L2.

The thermocouple 65 is a heater thermocouple and is configured to detect a temperature between the outer tube 12 and the heater structure 40 in each control zone. Thermocouple 65 is configured to measure the ambient temperature near heat generator 56 in each control zone. The temperature detected by the thermocouple 65 is hereinafter referred to as a heater temperature. Further, the temperature of the heat generator 56 may be used as the heater temperature.

The thermocouple 66 is a cascade thermocouple and detects a temperature between the outer tube 12 and the inner tube 13 in each control zone. Thermocouple 66 is configured to measure an in-furnace temperature, which is the temperature of the process chamber 14 in each control zone. The temperature detected by the thermocouple 66 is hereinafter referred to as the in-furnace temperature.

Based on the temperature information detected by the thermocouples 65 and 66 in each control zone, the temperature controller 64 is configured to regulate a state of supply an electric power to the heat generator 56 in each control zone and control the temperature of the process chamber 14 at a desired timing to reach a processing temperature set by a controller 200.

Further, in the case 41, a check damper 104 as a back-diffusion preventer is installed at each zone. A cooling gas 90 as a cooling medium is supplied to an internal space 75 via a gas flow path 107 by opening/closing the check damper 104. When the cooling gas 90 is not supplied from a gas source (not shown), the check damper 104 is closed so that the atmosphere of the internal space 75 does not flow back. The opening pressure of the check damper 104 may be changed depending on the zone. Further, a heat insulation cloth as a blanket is provided between an outer peripheral surface of the sidewall 43 and an inner peripheral surface of the case 41 to absorb a thermal expansion of metal.

As shown in FIG. 1, a ceiling wall 80 as a ceiling covers the upper end of the sidewall 43 of the heat insulation structure 42 to close the internal space 75. The ceiling wall 80 is formed with an annular exhaust hole 81 as a portion of an exhaust path configured to exhaust the atmosphere of the internal space 75, and a lower end, which is the upstream side end of the exhaust hole 81, communicates with the internal space 75. The downstream side end of the exhaust hole 81 is connected to an exhaust duct 82. The exhaust duct 82 is connected to an exhaust fan 84. The exhaust fan 84 is configured to supply the cooling gas 90 as the cooling medium to a cooling structure as a cooler, which will be described later, and discharge the cooling gas 90 via the exhaust duct 82.

Each of the pressure controller 21, the gas flow rate controller 24, the drive controller 28, the temperature controller 64, and a cooling controller 300 is configured to be electrically connected to the controller 200 and be capable of communicating with the controller 200. The pressure controller 21, the gas flow rate controller 24, the drive controller 28, the temperature controller 64, and the cooling controller 300, which will be described later, are configured to be controlled according to instructions from the controller 200, respectively.

### [Configuration of Cooler 301]

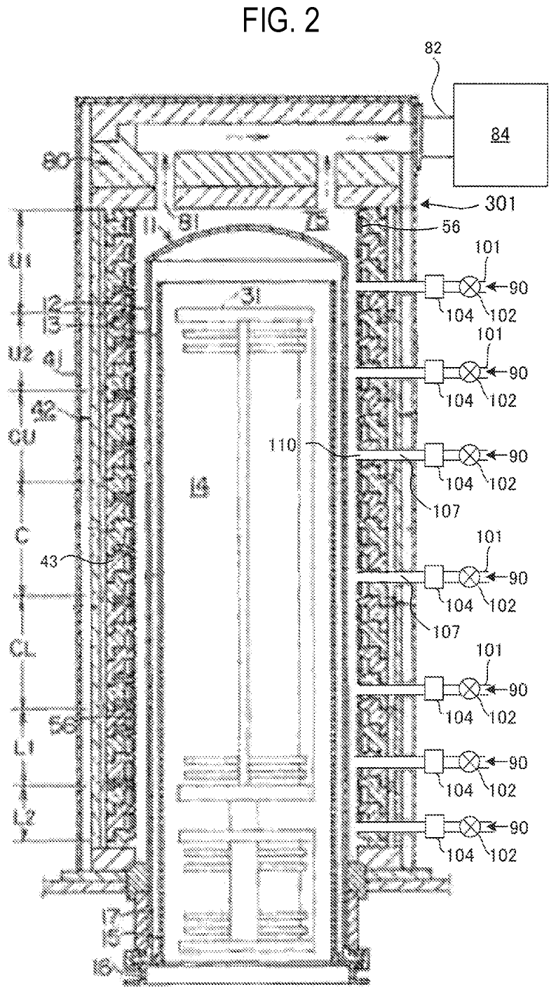

Next, a cooler 301 in the embodiments of the present disclosure will be described in detail with reference to FIG. 2.

The cooler 301 in the embodiments of the present disclosure is configured such that the cooler 301 is divided into a plurality of cooling zones U1, U2, CU, C, CL, L1, and L2 corresponding to a plurality of control zones, and each of the cooling zone is provided with an intake pipe 101 configured to supply the cooling gas 90, a cooling valve 102 installed at the intake pipe 101 and serving as a conductance valve configured to regulate the flow rate of the gas, and a plurality of opening holes (rapid cooling holes) 110 configured to eject the cooling gas toward the process tube 11. The cooling valve 102 supplies the cooling gas 90 as the cooling medium to the internal space 75 between the heater structure 40 and the process tube 11.

By opening/closing the cooling valve 102, the flow rate of the cooling gas 90 introduced into the intake pipe 101 is set according to a zone length ratio of each cooling zone, and the flow rate and flow velocity of the gas ejected from the opening holes 110 toward the process tube 11 are regulated. That is, the cooling controller 300 may regulate an opening state of the cooling valve 102 according to components in the intake pipe 101, thereby changing the flow rate and flow velocity of the cooling gas 90, which is introduced into each cooling zone. That is, the cooling valve 102 is configured to be controllable to different opening state in each cooling zone. The cooling valve 102 is configured to be capable of being controlled by the cooling controller 300.

Further, the check damper 104 is installed at the downstream side of the cooling valve 102 of the intake pipe 101 to prevent back-diffusion of the atmosphere from the process chamber 14. The cooling gas 90 is exhausted from the exhaust hole 81 installed above the internal space 75. Therefore, the check damper 104 is installed at each zone to efficiently store the cooling gas 90 and prevents convection between the intake pipe 101 and the heat insulation structure 42 when rapid cooling is not used.

Further, the opening holes 110 are provided such that the flow rate and flow velocity of the cooling gas 90 ejected to each cooling zone (for example, U2, CU, C, CL, and L1 in FIG. 2) from approximately the same height as the top of a region where the wafers 1 placed on the boat 31 are held to the bottom of the region where the wafers 1 are held are uniform. Specifically, the opening holes 110 are provided at equal intervals in the circumferential direction and the vertical direction within the cooling zone and are configured to be ejected into the internal space 75 via the gas flow path 107.

The heat insulation structure 42 used in the above-described heater structure 40 is also used as the cooler 301. As described above, the heat insulation structure 42 includes the sidewall 43 formed in a cylindrical shape, and the sidewall 43 is formed in a multi-layer structure. In this case, the sidewall 43 is configured to be divided into the plurality of cooling zones U1, U2, CU, C, CL, L1, and L2 in the vertical direction. For example, the partition may be configured to separate the sidewall 43 into the plurality of cooling zones U1, U2, CU, C, CL, L1, and L2 in the vertical direction, and a space may be provided between the partition 105 and the sidewall 43. The gas flow path 107 is configured to cause the intake pipe 101 and the internal space 75 to be in fluid communication with each other, and eject the cooling gas 90 into the internal space 75 via the opening holes 110 for each cooling zone.

Further, the opening holes 110 are arranged such that the ejected cooling gas 90 avoids the heat generator 56.

Further, in the embodiments of the present disclosure, the partition 105 is disposed such that the number of control zones is equal to the number of cooling zones. Without being limited to this form, the number of control zones and the number of cooling zones are arbitrarily set.

The exhaust duct 82 is connected to an exhaust fan 84 and is configured to discharge the cooling gas 90 by a discharge function of the exhaust fan 84.

Further, the cooling controller 300 is electrically connected to the cooling valve 102 and is configured to instruct the opening state of the cooling valve 102. Further, the cooling controller 300 is electrically connected to the exhaust fan 84 and is configured to instruct on/off operation of the exhaust fan 84.

The cooler 301 in the embodiments of the present disclosure regulates the opening state of the cooling valve 102 for each cooling zone by the cooling controller 300 and at the same time, turns on activation of the exhaust fan 84, such that the flow rate of the supplied cooling gas may be regulated for each cooling zone. As a result, a cooling capacity may be regulated for each cooling zone.

### [Structure of Controller]

Next, a structure of the controller 200 will be illustrated.

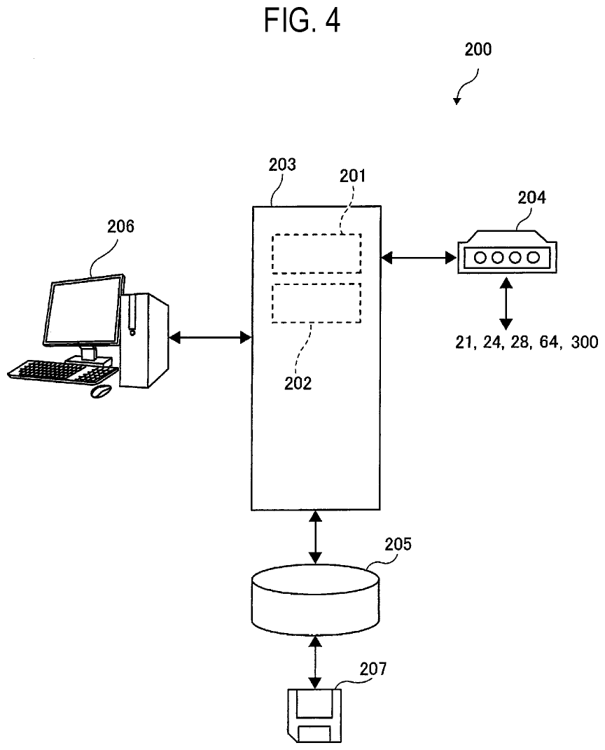

As shown in FIG. 4, the controller 200 includes a computer frame 203 including a CPU (Central Processing Unit) 201, a memory 202, etc., a communication interface (IF) 204 as a communicator, a storage 205 as a storage part, and a display/input device 206 as an operation part. That is, the controller 200 includes a constituent component as a general computer.

The CPU 201 constitutes a core of the operation part, executes control programs stored in the storage 205, and executes process recipes (for example, recipes for process) recorded in the storage 205 according to instructions from the display/input device 206.

Further, as a recording medium 207 configured to store an operation program of the CPU 201, a ROM (Read Only Memory), an EEPROM (Electrically Erasable Programmable Read Only Memory), a flash memory, a hard disk, or the like is used. Here, a RAM (Random Access Memory) functions as a work area for the CPU.

The communicator 204 is electrically connected to the pressure controller 21, the gas flow rate controller 24, the drive controller 28, the temperature controller 64, and the cooling controller 300 (these may be collectively referred to as sub-controllers) and may exchange data about operations of the respective components.

The storage 205 includes a program storage area that stores files of the above-described process recipe and the like. This program storage area is configured to store a program that causes the substrate processing apparatus to control a heater supply power such that a predicted temperature column calculated according to an in-furnace temperature prediction model, which is stored in advance, approaches a future target temperature column, and a program that causes the substrate processing apparatus to regulate the opening state of the cooling valve 102 to minimize an error between a predicted temperature column and a target temperature column calculated from a rate of change from the present target temperature to the final target temperature when the change occurs, according to a rapid cooling prediction model that includes information of the exhaust fan 84, a final target temperature that is a future target, and the opening state of the cooling valve 102, which will be described below in the embodiments, and estimates a predicted temperature that predicts at least one selected from the group of the heater temperature and the in-furnace temperature. Further, at least the above-described prediction model and various parameters for realizing the above-described prediction model are stored in a parameter storage area (not shown). Further, at least each prediction model in a predetermined temperature zone is stored.

In the embodiments of the present disclosure, the controller 200 is described as an example, but the present disclosure is not limited thereto and may be implemented by using a normal computer system. For example, the above-described processes may be executed by installing a program that executes the above-described processes in a general-purpose computer from the recording medium 207 such as a CD-ROM, a USB, or the like storing the program. Further, the communicator 204 such as a communication line, a communication network, or a communication system may be used. In this case, for example, the program may be posted on a bulletin board of the communication network and may be provided by being superimposed on a carrier wave via a network. By activating the program provided in this way and executing the program in the same manner as other application programs under the control of an OS (Operating System), the above-described processes may be executed.

### [Configuration of Cooling Controller]

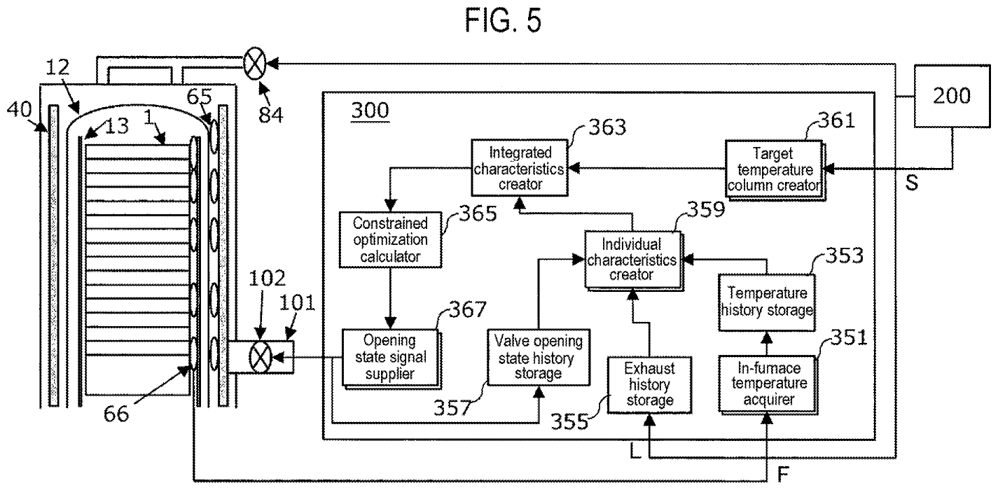

Next, a control configuration of the cooling controller 300 will be described with reference to FIG. 5.

The cooling controller 300 includes an in-furnace temperature acquirer 351, a temperature history storage 353, an exhaust history storage 355, a valve opening state history storage 357, an individual characteristics creator 359, a target temperature column creator 361, an integrated characteristics creator 363, a constrained optimization calculator 365, and an opening state signal supplier 367.

A target temperature from the controller 200 is input to an input terminal S. The in-furnace temperature from the thermocouple 66 is input to an input terminal F. Information on the on/off signal of the exhaust fan 84 from the controller 200 is input to an input terminal L.

Although there are as many target temperatures, input terminals S, and input terminals F as thermocouples 66, the respective ones thereof are shown in FIG. 4 because of the same configuration.

The intake pipe 101 and the cooling valve 102 are installed for each cooling zone as described above, but the respective ones thereof are shown in FIG. 5 for explanation. That is, the opening state of the cooling valve 102 may be different in each zone, and the cooling gas is supplied to the intake pipe 101 for each zone.

The same number of thermocouples 66 as cooling zones are arranged at positions corresponding to the cooling zones in the inner space of the inner tube 13 and convert the temperature in the vicinity of the wafer 1 into a minute voltage and output the same.

The cooling controller 300 is configured to acquire input signals from the input terminal S, the input terminal F, and the input terminal L every minute time, and update and output an output signal every minute time, according to a preset control cycle.

The in-furnace temperature acquirer 351 acquires minute power of the thermocouple 66, smoothes the acquired minute power for noise removal, and converts the same into a detection temperature according to its physical characteristics. That is, the in-furnace temperature acquirer 351 acquires the in-furnace temperature detected by the thermocouple 66. The in-furnace temperature acquirer 351 is present for the number of thermocouples 66.

The temperature history storage 353 receives the in-furnace temperatures or heater temperatures of zones from the in-furnace temperature acquirer 351 and stores data thereof in a temperature history storage area for a certain period of time. The temperature history storage 353 sequentially writes the temperatures in the temperature history storage area at predetermined intervals from the first acquired temperature. After the temperature history storage area is filled with data, the oldest data is discarded and new data is written in that position. In this way, the temperature history storage 353 is configured to be capable of storing past temperatures for a certain period of time from the present.

A temperature written in a process at a certain time t is treated as a temperature of one time before the present time (for example, displayed as y(t-1) in Equation 1) to unify display related to time. The received temperature is a temperature calculated from an average electromotive force of the thermocouple 66 up to the writing time.

The exhaust history storage 355 receives an on/off signal of the exhaust fan 84 from the controller 200 and stores data regarding the on/off signal of the exhaust fan 84 input to an exhaust history storage area for a certain period of time.

The valve opening state history storage 357 receives opening state information output to the cooling valves 102 of the zones and stores data thereof in a valve opening state history storage for a certain period of time. The valve opening state history storage 357 sequentially writes the opening states in the valve opening state history storage area at predetermined intervals from the first acquired opening state. After the valve opening state history storage area is filled with data, the oldest data is discarded and new data is written in that position. In this way, the valve opening state history storage 357 is configured to be capable of storing past opening states for a certain period from the present.

An opening state written in a process at a certain time t is treated as a temperature of one time before the present time (for example, displayed as Vₐ(t-1) in Equation 1) to unify display related to time. The received opening state is an opening state calculated in the previous process and is continuously output until the present time.

The individual characteristics creator 359 acquires from the storage 205 a rapid cooling prediction model as a prediction model of a certain cooling zone, which will be described later in detail, acquires predetermined past temperature data of the in-furnace temperature or heater temperature from the temperature history storage 353, acquires data related to predetermined past on/off of the exhaust fan 84 from the exhaust history storage 355, acquires predetermined past opening state data of the cooling valve 102 from the valve opening state history storage 357, and calculates an individual input response characteristics matrix Sₛᵣ and an individual zero response characteristics vector S_{zr} to be described below in Equations 2 and 3. The individual input response characteristics matrix Sₛᵣ and the individual zero response characteristics vector S_{zr} are calculated by the number of in-furnace temperatures to be controlled (=the number of zone divisions). As described above, the rapid cooling prediction model is described as being acquired from the controller 200, but, for example, a rapid cooling prediction model storage may be installed in the cooling controller 300. The above-described structure is just an example.

### [Rapid Cooling Prediction Model]

The rapid cooling prediction model is an equation that calculates a predicted temperature which predicts at least one selected from the group of the heater temperature and the in-furnace temperature, and uses the following equation 1.

$$\begin{matrix}[ Formula 1 ] & \\ \hat{y} ( t ) = y ( t - 1 ) + {a}_{1} \cdot \{ y ( t - 1 ) - y 0 \} \cdot {V}_{a} ( t - 1 ) + {a}_{2} \cdot \{ y ( t - 1 ) - y 0 \} \cdot {V}_{a} ( t - 2 ) + … + {a}_{n} \cdot \{ y ( t - 1 ) - y 0 \} \cdot {V}_{a} ( t - n ) + {b}_{1} \cdot \{ y ( t - 1 ) - y 0 \} \cdot {V}_{b} ( t - 1 ) + {b}_{2} \cdot \{ y ( t - 1 ) - y 0 \} \cdot {V}_{b} ( t - 2 ) + … + {b}_{n} \cdot y ( t - 1 ) - y 0 \} \cdot {V}_{b} ( t - n ) + {c}_{1} \cdot \{ y ( t - 1 ) - y 0 \} \cdot {V}_{c} ( t - 1 ) + {c}_{2} \cdot \{ y ( t - 1 ) - y 0 \} \cdot {V}_{c} ( t - 2 ) + … + {c}_{n} \cdot y ( t - 1 ) - y 0 \} \cdot {V}_{c} ( t - n ) + d \cdot \{ y ( t - 1 ) - y 0 \} \cdot \{ f ( t - 1 ) + … + f ( t - m ) \} / m & ( Equation 1 )\end{matrix}$$

$$\text{?} \qquad [ Formula 2 ]$$

$$\text{?} \text{indicates text missing or illegible when filed}$$

where, ŷ(t) is a predicted temperature at time t, and y(t-1) is a temperature at one time before the present time,

Vₐ(t-1),Vₐ(t-2), . . . ,Vₐ(t-n) are opening states of relevant cooling zones at one time, two times, . . . , and n times before the present time,

V_{b}(t-1),V_{b}(t-2), . . . ,V_{b}(t-n) are opening states of zones adjacent to one side of the relevant cooling zones at one time, two times, . . . , and n times before the present time,

V_{c}(t-1),V_{c}(t-2), . . . ,V_{c}(t-n)are opening states of zones adjacent to the other side of the relevant cooling zones at one time, two times, . . . , and n times before the present time, and

f(t-1),f(t-2), . . . ,f(t-m) are on (=1)/off (=0) data of the exhaust fan 84 at one time, two times, . . . , and m times before the present time.

y0 is a reference temperature, which is assumed to be around room temperature, for example. The reference temperature y0 is a temperature within a range of 20 degrees C. or higher and 30 degrees C. or lower, a₁, . . . , aₙ, b₁, . . . , bₙ, c₁, . . . , cₙ, and d are predetermined coefficients, and values of n and m are preset values and indicate the number of demanded past data. The prediction model may be stored for each cooling zone and used in control operation. That is, the rapid cooling prediction model corresponds to the respective temperature zones.

According to Equation 1, when the temperature at one time before the present time is the reference temperature y0, “y(t-1)−y0” becomes zero, and as a result,

ŷ(t)=y(t-1) [Formula 3]

Therefore, the predicted temperature=the temperature at one time before the present time =the reference temperature y0. In a case where the in-furnace temperature is room temperature, the in-furnace temperature will not change even when the opening state of the cooling valve 102 is fully opened to supply the maximum flow rate of the cooling gas (=room temperature). That shows that Equation 1 is valid at the reference temperature.

Further, according to Equation 1, for example, in a case where the prediction model is a rapid cooling prediction model regarding the temperature of the C zone, depending on each coefficient, the opening states of the cooling valve 102 in the adjacent CU zone and CL zone as well as the opening state of the cooling valve 102 in the C zone influence the predicted temperature. This makes it possible to express mutual interference between zones depending on each coefficient. Further, in the rapid cooling prediction model of Equation 1, by using the data of on (=1)/off (=0) of the exhaust fan 84 as a constant term, it is possible to improve a temperature error between zones at the start of rapid cooling. Here, even when the exhaust fan 84 is driven, since the cooling valves 102 are entirely closed until immediately before the start of rapid cooling, although it may be thought that the in-furnace temperature will not be influenced, by considering an influence of exhausting the in-furnace atmosphere by the operation of the exhaust fan 84 for a minute time at the start of rapid cooling, a temperature error between zones at the start of rapid cooling is improved, thereby improving a temperature controllability.

Here, the adjacent zones are set in advance in consideration of cooling characteristics. For example, two adjacent zones may be demanded depending on a state of mutual interference. Further, due to characteristics of the cooler, the cooling gas flows upward in the internal space 75, so, for example, two adjacent zones on the vertically lower side may be set.

Further, according to Equation 1, even in a case where the opening states of the cooling valves 102 in the relevant zone and adjacent zones are zero (=fully closed), the predicted temperature changes due to the term related to d. This makes it possible to express cooling other than the cooling by the cooling gas 90 from the intake pipe 101, for example, natural cooling or cooling by unintended draft.

The above-described Equation 1 is represented by a state space model as shown in the following Equation 2.

{_{y(t)=C·x(t)}^{x(t+1)=A·x(t)+B·u(t)} (Equation 2)[Formula 4]

Here, matrices A, B, and C are as follows. It should be noted that n=4 and m=3 were used for simplicity of notation.

$$A = [ \begin{matrix}1 & {a}_{2} & {a}_{3} & {a}_{4} & {b}_{2} & {b}_{3} & {b}_{4} & {c}_{2} & {c}_{3} & {c}_{4} \\ 0 & 0 & 0 & 0 & 0 & 0 & 0 & 0 & 0 & 0 \\ 0 & 1 & 0 & 0 & 0 & 0 & 0 & 0 & 0 & 0 \\ 0 & 0 & 1 & 0 & 0 & 0 & 0 & 0 & 0 & 0 \\ 0 & 0 & 0 & 0 & 0 & 0 & 0 & 0 & 0 & 0 \\ 0 & 0 & 0 & 0 & 1 & 0 & 0 & 0 & 0 & 0 \\ 0 & 0 & 0 & 0 & 0 & 1 & 0 & 0 & 0 & 0 \\ 0 & 0 & 0 & 0 & 0 & 0 & 0 & 0 & 0 & 0 \\ 0 & 0 & 0 & 0 & 0 & 0 & 0 & 1 & 0 & 0 \\ 0 & 0 & 0 & 0 & 0 & 0 & 0 & 0 & 1 & 0\end{matrix} ] \qquad [ Formula 5 ]$$

$$B = [ \begin{matrix}{a}_{1} & {b}_{1} & {c}_{1} & d \\ 1 & 0 & 0 & 0 \\ 0 & 0 & 0 & 0 \\ 0 & 0 & 0 & 0 \\ 0 & 1 & 0 & 0 \\ 0 & 0 & 0 & 0 \\ 0 & 0 & 0 & 0 \\ 0 & 0 & 1 & 0 \\ 0 & 0 & 0 & 0 \\ 0 & 0 & 0 & 0\end{matrix} ] \\ c = [ \begin{matrix}1 & 0 & 0 & 0 & 0 & 0 & 0 & 0 & 0 & 0\end{matrix} ] \qquad [ Formula 6 ]$$

Further, vectors x(t) and u(t) and output y(t) are as follows.

$$x ( t ) = [ \begin{matrix}y ( t ) \\ Y \cdot {V}_{a} ( t - 1 ) \\ Y \cdot {V}_{a} ( t - 2 ) \\ Y \cdot {V}_{a} ( t - 3 ) \\ Y \cdot {V}_{b} ( t - 1 ) \\ Y \cdot {V}_{b} ( t - 2 ) \\ Y \cdot {V}_{b} ( t - 3 ) \\ Y \cdot {V}_{c} ( t - 1 ) \\ Y \cdot {V}_{c} ( t - 2 ) \\ Y \cdot {V}_{c} ( t - 3 )\end{matrix} ] \qquad [ Formula 7 ]$$

$$u ( t ) = [ \begin{matrix}Y \cdot {V}_{a} ( t ) \\ Y \cdot {V}_{b} ( t ) \\ Y \cdot {V}_{c} ( t ) \\ Y \cdot \{ f ( t ) + f ( t - 1 ) + f ( t - 2 ) \} / 3\end{matrix} ] \\ y ( t ) = \hat{y} ( t ) \qquad [ Formula 8 ]$$

where, Y {y(t)−y0}

In Equation 2, when u(t) is input at time t, and then is continuously input as it is, the predicted temperature after t+1 is as shown in the following Equation 3.

$$\begin{matrix}[ Formula 9 ] & \\ [ \begin{matrix}\hat{y} ( t + 1 ) \\ \hat{y} ( t + 2 ) \\ \hat{y} ( t + 3 ) \\ ⋮\end{matrix} ] = [ \begin{matrix}y ( t + 1 ) \\ y ( t + 2 ) \\ y ( t + 3 ) \\ ⋮\end{matrix} ] = [ \begin{matrix}C \cdot {A}^{2} \\ C \cdot {A}^{3} \\ C \cdot {A}^{4} \\ ⋮\end{matrix} ] \cdot x ( t - 1 ) + [ \begin{matrix}C \cdot A \cdot B \\ C \cdot {A}^{2} \cdot B \\ C \cdot {A}^{3} \cdot B \\ ⋮\end{matrix} ] \cdot u ( t - 1 ) + [ \begin{matrix}C \cdot B \\ {\sum }_{i = 0}^{1} C \cdot {A}^{i} \cdot B \\ {\sum }_{i = 0}^{2} C \cdot {A}^{i} \cdot B \\ ⋮\end{matrix} ] \cdot u ( t ) \\ \hat{y} ( t ) = {S}_{zr} + {S}_{sr} \cdot u ( t ) & ( Equation 3 )\end{matrix}$$

$$where , \\ \hat{y} ( t ) = [ \begin{matrix}\hat{y} ( t + 1 ) \\ \hat{y} ( t + 2 ) \\ \hat{y} ( t + 3 ) \\ ⋮\end{matrix} ] , \\ {S}_{zr} = [ \begin{matrix}C \cdot {A}^{2} \\ C \cdot {A}^{3} \\ C \cdot {A}^{4} \\ ⋮\end{matrix} ] \cdot x ( t - 1 ) + [ \begin{matrix}C \cdot A \cdot B \\ C \cdot {A}^{2} \cdot B \\ C \cdot {A}^{3} \cdot B \\ ⋮\end{matrix} ] \cdot u ( t - 1 ) , \\ {S}_{sr} = [ \begin{matrix}C \cdot B \\ {\sum }_{i = 0}^{1} C \cdot {A}^{i} \cdot B \\ {\sum }_{i = 0}^{2} C \cdot {A}^{i} \cdot B \\ ⋮\end{matrix} ] \qquad [ Formula 10 ]$$

ŷ(t) is a predicted temperature vector.

In Equation 2, n=4 and m=3 are exemplified for simplicity of notation, but Equation 3 is not limited thereto. Further, in Equation 3, S_{zr} is an individual zero response characteristics vector, and Sₛᵣ is an individual input response characteristics matrix.

The number of rows is calculated as permissible depending on the control cycle and the operation processing performance of a CPU used by a controller.

The individual zero response characteristics vector S_{zr} indicates an amount of change in the predicted temperature vector that changes under the influence by the past temperature and past opening state of the cooling valve 102. Further, the individual input response characteristics matrix Sₛᵣ indicates an amount of change in the predicted temperature vector that changes under the influence by the opening state of the cooling valve 102 calculated at the present time.

Hereinafter, when the individual input response characteristics matrix Sₛᵣ, the individual zero response characteristics vector S_{zr}, and the predicted temperature vector are distinguished by the corresponding zones, an individual input response characteristics matrix corresponding to zone a is denoted as Sₛᵣ₋ₐ, and an individual zero response characteristics vector corresponding to zone b is denoted as S_{zr-b}, and so on.

### [Formula 11]

Further, a predicted temperature vector corresponding to zone e is denoted as ŷₑ(t) and so on.

The target temperature column creator 361 receives a target temperature, a present target temperature, and a ramp rate from the controller 200 at the timing when a set temperature is updated, and calculates an individual target temperature column vector S_{tg}. The ramp rate indicates a rate of change from the present target temperature to the final target temperature that will be the future target when the change occurs. For example, in a case where the ramp rate is set to 1 degree C./min, it is an indication of change at a rate of 1 degree C. for one minute. For example, when the present target temperature is 100 degrees C., an updated set temperature is 200 degrees C., and the ramp rate is 10 degrees C./min, information received from the controller 200 is that the target temperature=200 degrees C., the present target temperature=100 degrees C., and the ramp rate=10 degrees C./min. Then, before the present target temperature reaches 200 degrees C., for example, when it is 150 degrees C., and when the set temperature is updated to 300 degrees C. and the ramp rate is updated to 1 degrees C./min, the target temperature is 300 degrees C., the present target temperature is 150 degrees C., and the ramp rate is 1 degree C./min.

Then, the target temperature column creator 361 switches the individual target temperature column vector S_{tg} created when the ramp rate is zero and when the ramp rate is other than zero.

First, when the ramp rate is zero, the target temperature column creator 361 calculates the individual target temperature column vector S_{tg} according to a reference set value of:
(1) Ramping temperature deviation=target temperature−present target temperature
(2) Ramping time=absolute value (ramping temperature deviation)/reference ramp rate
(3) Reference set value=present target temperature+ramping temperature deviation×(1−exp (elapsed time÷(ramping time÷time constant))

For example, 1.0 is set as the time constant.

Next, when the ramp rate is other than zero, the target temperature column creator 361 calculates the individual target temperature column vector S_{tg} according to a reference set value of:
(1) Ramping temperature deviation=target temperature−present target temperature
(2) Ramping time=absolute value (ramping temperature deviation) ramp rate
(3) Reference set value=present target temperature+ramping temperature deviation× (elapsed time÷ramping time)

The individual target temperature column vector S_{tg} is expressed as in Equation 4 for the following explanation.

$$\begin{matrix}[ Formula 12 ] & \\ {S}_{tg} ( t ) = [ \begin{matrix}{S}_{tg} ( t + 1 ) \\ {S}_{tg} ( t + 2 ) \\ {S}_{tg} ( t + 3 ) \\ ⋮\end{matrix} ] & ( Equation 4 )\end{matrix}$$

The time and the number of rows in Equation 4 correspond to those in Equation 3 and the like. The target temperature column creator 361 exist in the same number as the temperatures to be controlled, that is, in the same number as the thermocouples 66.

Hereinafter, when the individual target temperature column vector S_{tg} is distinguished by the corresponding zones, an individual target temperature column vector corresponding to zone a is denoted as S_{tg-a}, an individual target temperature column vector corresponding to zone e is denoted as S_{tg-e}, and so on.

The integrated characteristics creator 363 receives the individual input response characteristics matrix Sₛᵣ and the individual zero response characteristic vector S_{zr} from multiple individual characteristics creators 359, receives the individual target temperature column vector S_{tg} from multiple target temperature column creators 361, and creates an integrated characteristics equation.

First, the individual input response characteristics matrix Sₛᵣ is transformed. The individual input response characteristics matrix Sₛᵣ indicates the amount of change in the predicted temperature when u(t) is input at time t and then is continuously input as it is. In a case where u(t) is not held and different values u(t) to u(t+Np-1) are input at the entirety of control timings, the second term on the right side of Equation 3 is as follows. Note that the number of rows in Equation 3 is Np.

$$[ \begin{matrix}C \cdot B & 0 & 0 & … & 0 \\ C \cdot A \cdot B & C \cdot B & 0 & … & 0 \\ C \cdot {A}^{2} \cdot B & C \cdot A \cdot B & C \cdot B & … & 0 \\ ⋮ & ⋮ & ⋮ & ⋱ & ⋮ \\ C \cdot {A}^{N p - 1} \cdot B & C \cdot {A}^{N p - 2} \cdot B & C \cdot {A}^{N p - 3} \cdot B & … & C \cdot B\end{matrix} ] \cdot [ \begin{matrix}u ( t ) \\ u ( t + 1 ) \\ u ( t + 2 ) \\ ⋮ \\ u ( t + N p - 1 )\end{matrix} ] \qquad [ Formula 13 ]$$

In well-known model predictive control, it is assumed that different values u(t) to u(t+Np-1) are input at the entirety of timings of operation processing, and these are obtained by calculation. However, since the operation processing performance of the CPU of the cooling controller 300 is not sufficient, in the present disclosure, by fixing an input pattern, the second term on the right side of Equation 3 is transformed as follows.

$${\overbrace{[ \begin{matrix}C \cdot B & 0 & 0 & … & 0 \\ C \cdot A \cdot B & C \cdot B & 0 & … & 0 \\ C \cdot {A}^{2} \cdot B & C \cdot A \cdot B & C \cdot B & … & 0 \\ ⋮ & ⋮ & ⋮ & ⋱ & ⋮ \\ C \cdot {A}^{N p - 1} \cdot B & C \cdot {A}^{N p - 2} \cdot B & C \cdot {A}^{N p - 3} \cdot B & … & C \cdot B\end{matrix} ]}}^{u ( t ) is held} \cdot [ \begin{matrix}u ( t ) \\ u ( t + 1 ) \\ u ( t + 2 ) \\ ⋮ \\ u ( t + N p - 1 )\end{matrix} ] \} u ( t ) is held \qquad [ Formula 14 ]$$

$$[ \begin{matrix}C \cdot B \\ C \cdot A \cdot B + C \cdot B \\ {\sum }_{i = 0}^{2} C \cdot {A}^{i} \cdot B \\ ⋮ \\ {\sum }_{i = 0}^{N p - 1} C \cdot {A}^{i} \cdot B\end{matrix} ] \cdot [ u ( t ) ] \qquad [ Formula 15 ]$$

By transforming the individual input response characteristic matrix Sₛᵣ as described above, the following Equation 5 is obtained from Equation 3.

$$\begin{matrix}[ Formula 16 ] & \\ \hat{y} ( t ) = {S}_{zr} + {S}_{dsr} \cdot u ( t ) \\ \hat{y} ( t ) = [ \begin{matrix}\hat{y} ( t + 1 ) \\ \hat{y} ( t + 2 ) \\ ⋮ \\ \hat{y} ( t + N p )\end{matrix} ] , \\ {S}_{zr} = [ \begin{matrix}C \cdot {A}^{2} \\ C \cdot {A}^{3} \\ ⋮ \\ C \cdot {A}^{N p + 1}\end{matrix} ] \cdot x ( t - 1 ) + [ \begin{matrix}C \cdot A \cdot B \\ C \cdot {A}^{2} \cdot B \\ ⋮ \\ C \cdot {A}^{N p} \cdot B\end{matrix} ] \cdot u ( t - 1 ) & ( Equation 5 )\end{matrix}$$

$${S}_{dsr} = [ \begin{matrix}C \cdot B \\ C \cdot A \cdot B + C \cdot B \\ {\sum }_{i = 0}^{2} C \cdot {A}^{i} \cdot B \\ ⋮ \\ {\sum }_{i = 0}^{N p - 1} C \cdot {A}^{i} \cdot B\end{matrix} ] \qquad [ Formula 17 ]$$

In Equation 5, S_{dsr} is set to the individual input response characteristics matrix again.

When distinguishing by the corresponding zones, an individual input response matrix corresponding to zone a is denoted as S_{dsr-a} and the like

Next, with respect to the above-described Equations 5 and 4, cooling zones to be controlled are arranged.

$$\begin{matrix}[ Formula 18 ] & \\ [ \begin{matrix}{\hat{y}}_{a} ( t ) \\ {\hat{y}}_{b} ( t ) \\ ⋮ \\ {\hat{y}}_{e} ( t )\end{matrix} ] = [ \begin{matrix}{S}_{zr - a} \\ {S}_{zr - b} \\ ⋮ \\ {S}_{zr - e}\end{matrix} ] + [ \begin{matrix}{S}_{dsr - a} \\ {S}_{dsr - b} \\ ⋮ \\ {S}_{dsr - e}\end{matrix} ] \cdot u ( t ) \\ = {U}_{zr} + {U}_{dsr} \cdot u ( t ) & ( Equation 6 )\end{matrix}$$

$$\begin{matrix}[ Formula 19 ] & \\ {U}_{tg} = [ \begin{matrix}{S}_{tg - a} ( t ) \\ {S}_{tg - b} ( t ) \\ ⋮ \\ {S}_{tg - e} ( t )\end{matrix} ] & ( Equation 7 )\end{matrix}$$

As described above, the integrated characteristics creator 363 calculates and outputs an integrated input response characteristics matrix U_{dsr}, an integrated zero response characteristics vector U_{zr}, and an integrated target temperature vector U_{tg} shown in Equations 6 and 7.

The constrained optimization calculator 365 receives the integrated input response characteristics matrix U_{dsr}, the integrated zero response characteristics vector U_{zr}, and the integrated target temperature vector U_{tg} from the integrated characteristics creator 363 and calculates an optimal opening state for the present time by a method called an effective constraint method which will be described later.

The number of the opening state signal suppliers 367 is the same as the number of divided cooling zones, that is, the number of connected cooling valves 102. The opening state signal supplier 367 acquires the corresponding opening state from the constrained optimization calculator 365 in a predetermined control cycle, and updates the opening state indication to the cooling valve 102.

### [First Effective Constraint Method]

A first effective constraint method used in the present disclosure will be described. The effective constraint method obtains a solution vector x that maximizes an evaluation function ƒ(x) given by the following Equation 8 under a constraint condition of the following Equation 9.

ƒ(x)=c^{T}·x−½x^{T}·Q·x (Equation 8)

b≥A·x (Equation 9)[Formula 20]

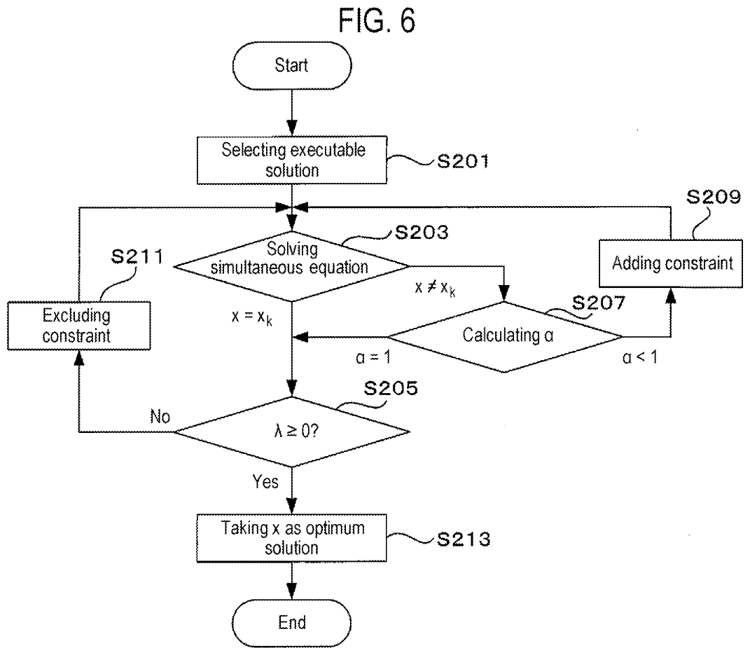

In Equations 8 and 9, c, Q, b, and A are given constant matrices or vectors. Also, a symbol T represents transposition. At this time, the effective constraint method may obtain the solution vector x by executing a flow shown in FIG. 6.

In S201, a solution xk within a range in which the equality sign in Equation 9 is not valid is selected. Then, Aₑ and bₑ are set to sets of rows in which the equality sign is valid among the rows in Equation 9. In S201, both Aₑ and bₑ are empty sets. Also, let A_{d} and b_{d} are set to sets of rows in which the equality sign is not valid among the rows of Equation 9. In S201, A_{d}=A and b_{d}=b.

In S203, the following simultaneous equation is solved, and the solutions thereof are defined as x and λ. In a case where x=xₖ, the flow proceeds to S205. In a case where x≠xₖ, the flow proceeds to S207.

$$[ \begin{matrix}Q & {A}_{e}^{T} \\ {A}_{e} & 0\end{matrix} ] \cdot [ \begin{matrix}x \\ λ\end{matrix} ] = [ \begin{matrix}c \\ {b}_{e}\end{matrix} ] \qquad [ Formula 21 ]$$

In S205, it is determined whether or not the entirety of elements of λ are 0 or more. In a case where the entirety of elements of λ are 0 or more, the flow proceeds to S213. In a case where the entirety of elements of λ are not 0 or more, the flow proceeds to S211.

In S207, α is obtained according to the following Equation 10, and bᵢ and aᵢ are rows extracted from A_{d} and b_{d}, respectively. In a case where α=1, the flow proceeds to S205. In a case where α<1, the flow proceeds to step S209.

$$[ Formula 22 ]$$

$$\overline{α} = {min}_{i ∈ d} [ \{ \begin{matrix}\frac{{b}_{i} - {a}_{i} \cdot {x}_{k}}{{a}_{i} \cdot ( x - {x}_{k} )} & ( 0 < denominator ) \\ 1 & ( denominator \leq 0 )\end{matrix} ] \qquad ( Equation 11 )$$

$$α = \{ \begin{matrix}\overline{α} & ( 0 < \overline{α} < 1 ) \\ 1 & ( 1 \leq \overline{α} )\end{matrix}$$

In S209, the constraint [bᵢ, aᵢ} used to obtain α(<1) according to Equation 10 is deleted from A_{d} and b_{d} and added to Aₑ and bₑ, and the flow proceeds to S203.

In S211, an element of λ that is the smallest negative value is selected, the corresponding constraint [bᵢ, aᵢ} of the constraints included in Aₑ and bₑ is deleted from Aₑ and bₑ and added to A_{d} and b_{d}, and the flow proceeds to S203.

In S213, the solution x obtained in S203 is taken as the optimum solution, and the flow ends.

The effective constraint method shown in FIG. 6 may obtain a solution that satisfies Equation 9 and maximizes Equation 8 by searching for combinations of rows in which the equality sign is valid among the rows of Equation 9 by using an incidental multiplier k.

### [Application to Control of Effective Constraint Method]

Next, a method of applying the effective constraint method in the present disclosure will be described.

In the integrated characteristics creator 363, the predicted temperature column (predicted temperature vector) of the in-furnace temperature may be obtained from Equation 6, and the target temperature column (integrated target temperature vector) may be obtained from Equation 7. Therefore, the constrained optimization calculator 365 uses a square of an error between the target temperature column and the predicted temperature column, as an evaluation function. The evaluation function V(u(t)) is given by the following Equation 11.

$$[ Formula 23 ]$$

$$V ( u ( t ) ) = {[ {U}_{tg} - ( {U}_{zr} + {U}_{dsr} \cdot u ( t ) ) ]}^{T} \cdot [ {U}_{tg} - ( {U}_{zr} + {U}_{dsr} \cdot u ( t ) ) ] = {[ {U}_{tg} - {U}_{zr} ]}^{T} \cdot [ {U}_{tg} - {U}_{zr} ] - {2 [ {U}_{tg} - {U}_{zr} ]}^{T} \cdot {U}_{dsr} \cdot ut ( t ) + {u}^{T} ( t ) \cdot {{U}_{dsr}}^{T} \cdot {U}_{dsr} \cdot ut ( t ) = ( constant term ) - 2 ( {[ {U}_{tg} - {U}_{zr} ]}^{T} \cdot {U}_{dsr} \cdot u ( t ) - \frac{1}{2} {u}^{T} ( t ) \cdot {{U}_{dsr}}^{T} \cdot {U}_{dsr} \cdot u ( t ) ) = ( constant term ) - 2 ( {[ {{U}_{dsr}}^{T} \cdot [ {U}_{tg} - {U}_{zr} ] ]}^{T} \cdot u ( t ) - \frac{1}{2} {u}^{T} ( t ) \cdot [ {{U}_{dsr}}^{T} \cdot {U}_{dsr} ] \cdot u ( t ) ) \qquad ( Equation 11 )$$

Comparing the inside of the outer parenthesis of the second term of Equation 11 with Equation 8, c and Q in Equation 8 may be replaced with the following equations.

c=U_{dsr}^{T}·[U_{tg}−U_{zr}],W=U_{dsr}^{T}·U_{dsr}

As a result, a solution that maximizes the inside of the outer parenthesis of the second term of Equation 11 may be obtained by the above-described effective constraint method. Therefore, a solution that minimizes the evaluation function V(u(t)) may be obtained, the evaluation function V(u(t)) that minimizes the square of the error between the target temperature column and the predicted temperature column is created, and the simultaneous equation is calculated to minimize this evaluation function V(u(t)). Then, by solving the simultaneous equation, the opening state of the cooling valve 102 included in the solution of the predicted temperature column may be acquired, and the cooling controller 300 regulates the opening state of the cooling valve 102.

Next, with respect to Equation 9 regarding the constraints, exemplifying the opening states of zones a to c for simplicity of notation, as shown in the following Equation 12, when the upper and lower limits on the left side of an arrow are given to power supply values kₐ, k_{b}, and λc of the respective zones, Equation 9 may be applied by setting the inequality as shown on the right side of the arrow. In the following Equation 12, LLₐ and ULₐ are the upper and lower limits of the power supply value for zone a, respectively, and similarly, LL_{b}, UL_{b}, LL_{c}, and UL_{c} are the upper and lower limits of the power supply values for zone b and zone c, respectively. For example, LLₐ and ULₐ are set to 0% and 100%, respectively.

$$[ Formula 25 ]$$

$$\begin{matrix}{LL}_{a} \leq {V}_{a} ( t ) \leq {UL}_{a} \\ {LL}_{b} \leq {V}_{b} ( t ) \leq {UL}_{b} \\ {LL}_{c} \leq {V}_{c} ( t ) \leq {UL}_{c}\end{matrix} ⇒ [ \begin{matrix}{UL}_{a} \\ {LL}_{a} \\ {UL}_{b} \\ {LL}_{b} \\ {UL}_{c} \\ {LL}_{c}\end{matrix} ] \geq [ \begin{matrix}1 & 0 & 0 \\ - 1 & 0 & 0 \\ 0 & 1 & 0 \\ 0 & - 1 & 0 \\ 0 & 0 & 1 \\ 0 & 0 & - 1\end{matrix} ] \cdot [ \begin{matrix}{V}_{a} ( t ) \\ {V}_{b} ( t ) \\ {V}_{c} ( t )\end{matrix} ] \qquad ( Equation 12 )$$

[Second Effective Constraint Method]

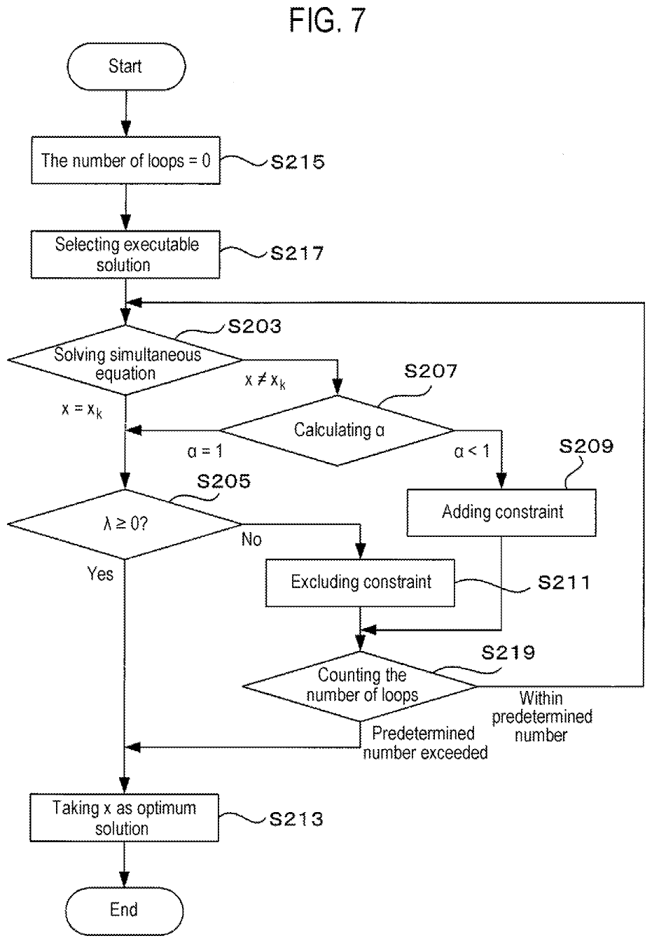

Next, a second effective constraint method that may be used in the present disclosure will be described. In the above-described effective constraint method shown in FIG. 6, in a case where an operation processing capability of the CPU is not sufficient, calculation may not end within a predetermined control cycle. Therefore, instead of the flow of FIG. 6, a flow of FIG. 7 is used to obtain the solution vector x.

The differences from the first effective constraint method in FIG. 6 are to add S215 immediately after the start, change S201 to S217, proceed with the flow from S209 and S211 to an added S219, and proceed with the flow to S203 or S213 depending on a determination in S219. In the following, differences from the first effective constraint method will be described.

In S215, the number of loops is initialized.

Then, in S217, a solution xl within a range in which the equality sign of Equation 9 is not valid is selected. In preparation for a case where the optimization calculation ends halfway in S219 which will be described later, in particular, the selected solution is the upper limit value of a range over which the equality sign of Equation 9 is not valid. For example, when the opening state of zone a is 0 Va(t) 100, the selected solution is Va(t)=99.9 and the like. By making such a selection, the constraint added in S209 gives priority to the upper limit constraint, so even in a case where the optimization calculation ends halfway, a safe calculation result may be obtained.

In S219, the number of loops is counted up, and in a case where it is within a predetermined number, the flow proceeds to S203. When it exceeds the predetermined number, the flow proceeds to S213 and ends with the solution x obtained in the previous S203 as the optimum solution.

By making the flow as shown in FIG. 7, since the calculation of the optimum solution may end with the minimum demanded process, the calculation may end within the predetermined control cycle.

### Second Embodiment of the Present Disclosure

Next, a second embodiment of the present disclosure will be described. In the cooling controller 300 according to the second embodiment of the present disclosure, a temperature detected by the thermocouple 65 instead of the thermocouple 66 is input to the in-furnace temperature acquirer 351. That is, the in-furnace temperature acquirer 351 acquires the heater temperature detected by the thermocouple 65 and controls the heater temperature according to the target temperature. Thus, even in a structure without the thermocouple 66, by using the temperature detected by the thermocouple 65, it is possible to obtain the same effects as in the above-described embodiments of the present disclosure.

### Third Embodiment of the Present Disclosure

Next, a third embodiment of the present disclosure will be described.

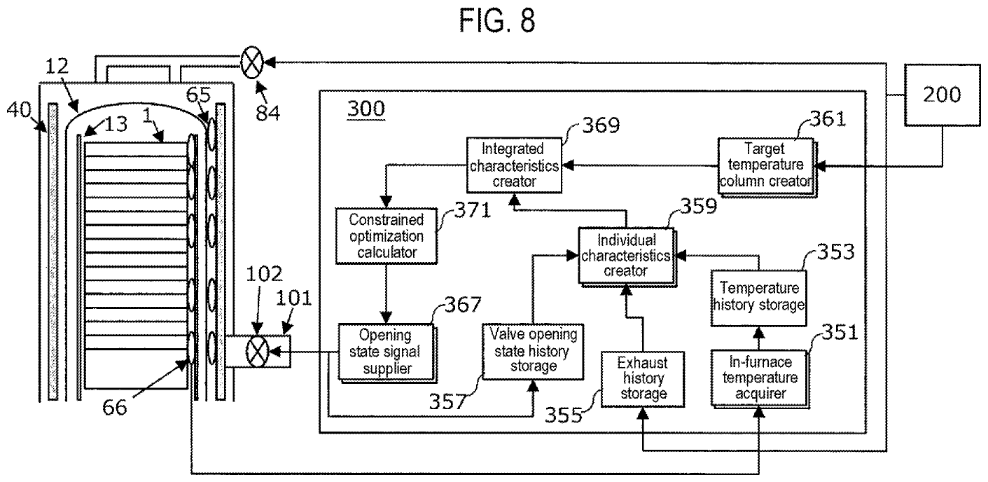

FIG. 8 is an internal control block diagram of the cooling controller 300 according to the third embodiment of the present disclosure. In the third embodiment, an integrated characteristics creator 369 is used instead of the integrated characteristics creator 363 and an optimization calculator 371 is used instead of the constrained optimization calculator 365 in the control block diagram shown in FIG. 5. In the following, portions different from the above-described control block shown in FIG. 5 will be described, and detailed description of the same portions will not be performed.

The integrated characteristics creator 369 receives the individual input response characteristics matrix Sₛᵣ and the individual zero response characteristics vector S_{zr} from the same number of individual characteristics creators 359 as zone divisions, receives the target temperature column vector S_{tg} from the same number of target temperature column creators 361 as zone divisions, and creates an integrated characteristic equation.

The integrated characteristics equation is created by a method shown in the following Equations 13 and 14 instead of Equations 6 and 7.

$$[ Formula 26 ]$$

$$[ \begin{matrix}{\hat{y}}_{a} ( t ) \\ {\hat{y}}_{b} ( t ) - {\hat{y}}_{a} ( t ) \\ ⋮ \\ {\hat{y}}_{e} ( t ) - {\hat{y}}_{a} ( t )\end{matrix} ] = [ \begin{matrix}{S}_{zr - a} \\ {S}_{zr - b} - {S}_{zr - a} \\ ⋮ \\ {S}_{zr - e} - {S}_{zr - a}\end{matrix} ] + [ \begin{matrix}{S}_{dsr - a} \\ {S}_{dsr - b} - {S}_{dsr - a} \\ ⋮ \\ {S}_{dsr - e} - {S}_{dsr - a}\end{matrix} ] \cdot u ( t ) = {U}_{zr} + {U}_{dsr} \cdot u ( t ) \qquad ( Equation 13 )$$

$$[ Formula 27 ]$$

$${U}_{tg} = [ \begin{matrix}{S}_{tg - a} \\ {S}_{tg - b} - {S}_{tg - a} \\ ⋮ \\ {S}_{tg - e} - {S}_{tg - a}\end{matrix} ] \qquad ( Equation 14 )$$

In Equations 13 and 14, differences from zone a are arranged in the second and subsequent rows, respectively. Using the zone a as a reference for the differences makes it possible to set a parameter or the like in advance. Although the zone a is herein used as the reference for the differences, a zone other than the zone a may be used as the reference. Also, the times and the number of rows in Equations 13 and 14 correspond to Equations 6 and 7.

Then, the integrated characteristics creator 369 calculates and outputs the integrated input response characteristics matrix U_{dsr}, the integrated zero response characteristics vector UT, and the integrated target temperature vector U_{tg} shown in Equations 13 and 14.

The constrained optimization calculator 371 receives the integrated input response characteristics matrix U_{dsr}, the integrated zero response characteristics vector UT, and the integrated target temperature vector U_{tg} from the integrated characteristics creator 369, and calculates the optimal opening state for the present time by the above-described effective constraint method.

The optimization calculator 371 uses, as an evaluation function, the square of an error between the target temperature column and the predicted temperature column for the reference zone and the sum of the squares of differences between the predicted temperature columns for the other zones and the predicted temperature column for the reference zone. In this case, a weighting matrix Z is taken into consideration for the sum of the squares of the differences between the predicted temperature columns for the other zones and the predicted temperature column for the reference zone. The evaluation function V(u(t)) is then given by Equation 15.

$$[ Formula 28 ]$$

$$V ( u ( t ) ) = {[ {U}_{tg} - ( {U}_{zr} + {U}_{dsr} \cdot u ( t ) ) ]}^{T} \cdot Z \cdot [ {U}_{tg} - ( {U}_{zr} + {U}_{dsr} \cdot u ( t ) ) ] = {[ {U}_{tg} - {U}_{zr} ]}^{T} \cdot Z \cdot [ {U}_{tg} - {U}_{zr} ] - {2 [ {U}_{tg} - {U}_{zr} ]}^{T} \cdot Z \cdot {U}_{dsr} \cdot ut ( t ) + {u}^{T} ( t ) \cdot {{U}_{dsr}}^{T} \cdot Z \cdot {U}_{dsr} \cdot ut ( t ) = ( constant term ) - 2 ( {[ {U}_{tg} - {U}_{zr} ]}^{T} \cdot Z \cdot {U}_{dsr} \cdot u ( t ) - \frac{1}{2} {u}^{T} ( t ) \cdot {{U}_{dsr}}^{T} \cdot Z \cdot {U}_{dsr} \cdot u ( t ) ) = ( constant term ) - 2 ( {[ {{U}_{dsr}}^{T} \cdot Z \cdot [ {U}_{tg} - {U}_{zr} ] ]}^{T} \cdot u ( t ) - \frac{1}{2} {u}^{T} ( t ) \cdot [ {{U}_{dsr}}^{T} \cdot Z \cdot {U}_{dsr} ] \cdot u ( t ) ) \qquad ( Equation 15 )$$

That is, when replacement is executed with the following:

c=U_{dsr}^{T}·Z·[U_{tg}−U_{zr}],Q=U_{dsr}T·Z·U_{dsr}, [Formula 29]

the above-described effective constraint method may be applied.

Here, the weighting matrix Z is a diagonal matrix in which 1 is assigned to the weight of the evaluation on the deviation of the reference zone and Z is assigned to the weight of the evaluation on the differences of the other zones from the reference zone. Z takes values of, for example, 1 to 10.

$$[ Formula 30 ]$$

$$Z = [ \begin{matrix}E & 0 & 0 & 0 \\ 0 & Z \cdot E & 0 & 0 \\ 0 & 0 & Z \cdot E & 0 \\ 0 & 0 & 0 & Z \cdot E\end{matrix} ] , \qquad ( Equation 16 )$$

$$E is a unit matrix$$

According to the control method of the cooling controller 300 shown in FIG. 8, when controlling the temperature, it is possible to control the temperature in consideration of the inter-zone temperature deviation of the temperature assigned to each zone, and it is possible to control the temperature drop of the temperature assigned to each zone at about the same time with the same temperature history.

[Configuration of Rapid Cooling Prediction Model Updating Process]

An automatic acquisition procedure for the rapid cooling prediction model exemplified in Equation 1 will be described. The coefficients of the rapid cooling prediction model (a₁, . . . , aₙ, b₁, . . . , bₙ, c₁, . . . , cₙ, and d in Equation 1) are determined according to this procedure.

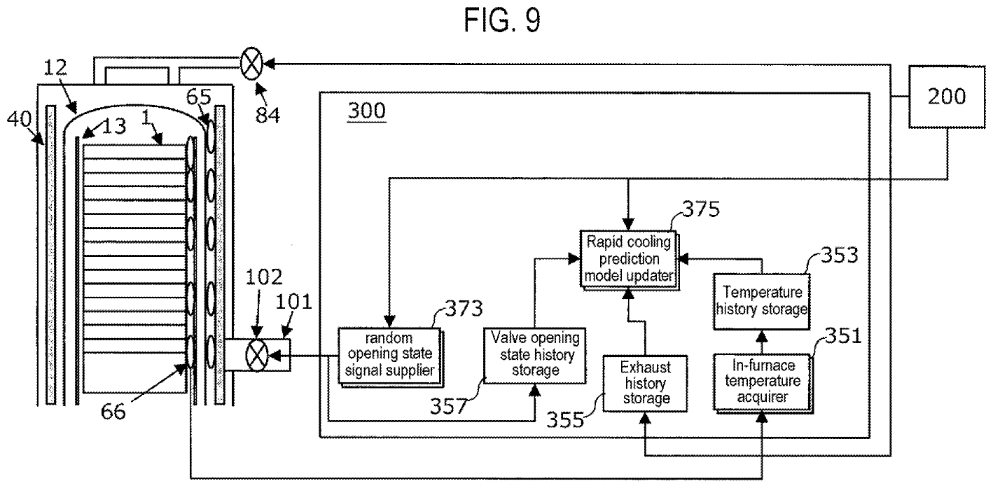

FIG. 9 is a block diagram of process performed by the cooling controller 300 when generating the rapid cooling prediction model.

A random opening state signal supplier 373 instructs the corresponding cooling valve 102 with an opening state randomly selected (hereinafter, referred to as a random opening state) from three discrete values according to a command from the controller 200. There are as many random opening state signal suppliers 373 as cooling zones, that is, cooling valves 102. Possible values of the random opening state and duration until change may be received from the controller 200 or may be set in advance by parameters or the like.

A rapid cooling prediction model updater 375 acquires the rapid cooling prediction model from the storage 205, acquires demanded past temperature data from the temperature history storage 353, acquire demanded past information on on/off of the exhaust fan 84 from the exhaust history storage 355, acquires demanded past information on the opening state from the valve opening state history storage 357, and calculates, updates, and rerecords the latest rapid cooling prediction model obtained at that time, according to a command from the controller 200. After starting, the rapid cooling prediction model is updated at a predetermined cycle, and the operation thereof is performed for a predetermined period of time before ending.

There are as many rapid cooling prediction model updaters 375 as cooling zones, that is, cooling valves 102. The number of terms of the rapid cooling prediction model (the values of n and m in Equation 1), the state of mutual interference (Equation 1), and the like may be received from the controller 200 or may be set in advance by parameters or the like. [Rapid Cooling Prediction Model Updating Method]

Next, a method of updating the rapid cooling prediction model performed by the rapid cooling prediction model updater 375 will be described. The updating method in the present disclosure uses a method called an iterative least square method. The following Equation 17 is a notation of Equation 1 using a matrix and a vector.

### [Formula 31]

A predicted value of [symbol] (t) of a difference between the predicted temperature and the temperature one time before the present time is represented as the following Equation 17.

$$\hat{Δ y} ( t ) = {x}^{T} ( t ) \cdot θ ( t ) \qquad ( Equation 17 )$$

$$x ( t ) = [ \begin{matrix}Y \cdot {V}_{a} ( t - 1 ) \\ ⋮ \\ Y \cdot {V}_{a} ( t - n ) \\ Y \cdot {V}_{b} ( t - 1 ) \\ ⋮ \\ Y \cdot {V}_{b} ( t - n ) \\ Y \cdot {V}_{c} ( t - 1 ) \\ ⋮ \\ Y \cdot {V}_{c} ( t - n ) \\ Y \cdot \{ f ( t - 1 ) + ⋯ + f ( t - m ) \} / m\end{matrix} ] ,$$

$$θ ( t ) = [ \begin{matrix}{a}_{1} ( t ) \\ ⋮ \\ {a}_{n} ( t ) \\ {b}_{1} ( t ) \\ ⋮ \\ {b}_{n} ( t ) \\ {c}_{1} ( t ) \\ ⋮ \\ {c}_{n} ( t ) \\ d ( t )\end{matrix} ]$$

where, Y=y(t-1)-y0

Here, the time t represents a process for the present time, and the reason the latest data among the elements of x(t) is Va(t-1) is that, as described above, the time of the opening state, etc. obtained in the process for the present time is set to t-1.

The latest coefficient θ(t) of the prediction model is calculated according to the following Equation 18.

$$[ Formula 32 ]$$

$$θ ( t ) = θ ( t - 1 ) + η ( t ) \cdot k ( t ) \qquad ( Equation 18 )$$

$$k ( t ) = \frac{P ( t - 1 ) \cdot x ( t - 1 )}{ρ + {x}^{T} ( t - 1 ) \cdot P ( t - 1 ) \cdot x ( t - 1 )}$$

$$η ( t ) = Δ y ( t - 1 ) - {x}^{T} ( t - 1 ) \cdot θ ( t - 1 )$$

$$P ( t ) = \frac{1}{ρ} ( P ( t - 1 ) - k ( t ) \cdot {x}^{T} ( t - 1 ) \cdot P ( t - 1 ) )$$

Here, Δy(t-1) is a difference between a temperature acquired at the present time and the temperature acquired at the last time (=y(t-1)-y(t-2)). ρ is a parameter called a forgetting factor and is set in advance as a parameter. P(t) is a coefficient error correlation matrix and is recorded with the rapid cooling prediction model whenever being updated. A unit matrix with, for example, 100 to 1,000 elements, is set as an initial value.

The coefficient θ(t) of the rapid cooling prediction model is recorded in a predetermined storage area within the cooling controller 300 after a preset time elapses.

### [Automatic Acquisition Procedure of Rapid Cooling Prediction Model]

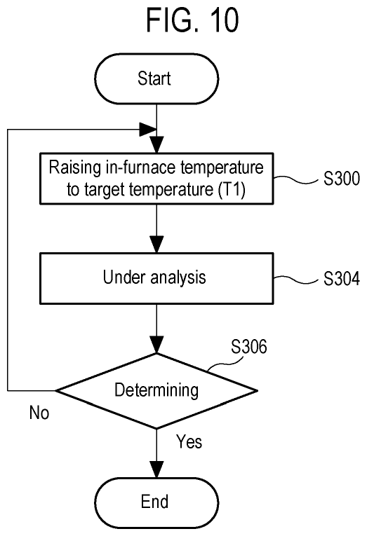

Next, a procedure for automatically acquiring the rapid cooling prediction model performed by the cooling controller 300 will be described with reference to FIG. 10.

In S300, according to an instruction from the controller 200, the in-furnace temperature is controlled to a target temperature T1. At this time, it is controlled by a feedback loop of the heater structure 40, the temperature controller 64, and the thermocouple 66.

In S304, the drive of the exhaust fan 84 is started (turned on) according to an instruction from the controller 200, and at the same time, the update of the rapid cooling prediction model is started in the cooling controller 300 according to an instruction from the controller 200 with a configuration shown in FIG. 9. As described with reference to FIG. 9, the cooling controller 300, on the one hand, independently instructs the cooling valve 102 of each cooling zone with a random opening state, and on the other hand, updates the rapid cooling prediction model (Equation 18). When a preset time elapses from the start time of this step, the instruction of the random opening state is stopped, and the rapid cooling prediction model is determined and recorded in a predetermined storage area in the cooling controller 300. At the end of this step, the controller 200 stops (turns off) the drive of the exhaust fan 84.

At S306, it is determined whether or not the rapid cooling prediction model determined at S304 is valid. The condition for determination adopts the number of times of execution of S304, a convergence state of the prediction model during execution of S304, or a combination thereof.

### [Formula 33]

The convergence state of the prediction model is determined by whether the amount of change in the coefficient of the cooling prediction model (=∥θ(t)−θ(T−1)∥; the norm of coefficient change) is larger than or smaller than a threshold value.

When the result of determination is not valid (=“No”), the procedure returns to S300. When the result of determination is valid (=“Yes”), the procedure for automatically acquiring the rapid cooling prediction model is ended. The determined valid rapid cooling prediction model is read out and used by the individual characteristics creator 359 when the temperature control of the present disclosure is performed in a temperature lowering step S5 which will be described later.

### [Second Rapid Cooling Prediction Model of the Present Disclosure]

Next, a second rapid cooling prediction model of the present disclosure will be described. In the rapid cooling prediction model of the above-described Equation 1, a preset value n of Equation 1 may be set to a sufficiently large value to ensure sufficient accuracy of the predicted temperature. However, since the operation processing performance of the CPU of the cooling controller 300 is not sufficient, when the value n is increased, the control operation may not be ended in a predetermined control cycle. Therefore, the present disclosers found that a rapid cooling prediction model of the following Equation 19 may be used instead of the rapid cooling prediction model of the above-described Equation 1.

$$[ Formula 34 ]$$

$$\hat{y} ( t ) = y ( t - k ) + {a}_{1} \cdot \{ y ( t - k ) - y 0 \} \cdot {V}_{a} ( t - k ) + {a}_{2} \cdot \{ y ( t - k ) - y 0 \} \cdot {V}_{a} ( t - 2 k ) + ⋯ + {a}_{n} \cdot \{ y ( t - k ) - y 0 \} \cdot {V}_{a} ( t - k ) + {b}_{1} \cdot \{ y ( t - k ) - y 0 \} \cdot {V}_{b} ( t - k ) + {b}_{2} \cdot \{ y ( t - k ) - y 0 \} \cdot {V}_{b} ( t - 2 k ) + ⋯ + {b}_{n} \cdot \{ y ( t - k ) - y 0 \} \cdot {V}_{b} ( t - nk ) + {c}_{1} \cdot \{ y ( t - k ) - y 0 \} \cdot {V}_{c} ( t - k ) + {c}_{2} \cdot \{ y ( t - k ) - y 0 \} \cdot {V}_{c} ( t - 2 k ) + ⋯ + {c}_{n} \cdot \{ y ( t - k ) - y 0 \} \cdot {V}_{c} ( t - nk ) + d \cdot \{ y ( t - k ) - y 0 \} \cdot \{ f ( t - k ) + ⋯ + f ( t - mk ) \} / m \qquad ( Equation 19 )$$

Here, for example, a natural number such as k=2 or k=10 is used,

y(t-k) is the deviation of a temperature k times before the present time from the reference temperature,

Vₐ(t-k), Va(t-2k), . . . ,Vₐ(t-nk) are opening states of the relevant cooling zone k times, 2k times, . . . , nk times before the present time,

V_{b}(t-k), V_{b}(t-2k), . . . , V_{b}(t-nk) are opening states of the zone adjacent to one side of the relevant cooling zone k times, 2k times, . . . , nk times before the present time,

V_{c}(t-k), V_{c}(t-2k), . . . , V_{c}(t-nk) are opening states of the zone adjacent to the other side of the relevant cooling zone before k times, 2k times, . . . , nk times before the present time,

f(t-k), f(t-2k), . . . , f(t-mk) are information about on (=1)/off (=0) of the exhaust fan 84 k times, 2k times, . . . , nk times before the present time, and the other elements are the same as those in the above-described Equation 1.

Then, Equation 19 matches the above-described Equation 1 when k=1. That is, Equation 19 uses data up to nk times before the present time when estimating the predicted temperature, but uses data for every k samples to suppress the amount of operation.

In a case where the data for every k samples is used, since outliers may be used due to noise or the like, the following Equation 20 may be used, which uses data for every k samples after low-pass filter processing, for example, simple moving average is performed.

$$[ Formula 35 ]$$

$$\hat{y} ( t ) = {y}_{ave} ( t - k ) + {a}_{1} \cdot \{ y ( t - k ) - y 0 \} \cdot {V}_{ave - a} ( t - k ) + {a}_{2} \cdot \{ y ( t - k ) - y 0 \} \cdot {V}_{ave - a} ( t - 2 k ) + ⋯ + {a}_{n} \cdot {V}_{ave - a} ( t - nk ) + {b}_{1} \cdot \{ y ( t - k ) - y 0 \} \cdot {V}_{ave - b} ( t - k ) + {b}_{2} \cdot \{ y ( t - k ) - y 0 \} \cdot {V}_{ave - b} ( t - 2 k ) + ⋯ + {b}_{n} \cdot \{ y ( t - k ) - y 0 \} \cdot {V}_{ave - a} ( t - nk ) + {c}_{1} \cdot \{ y ( t - k ) - y 0 \} \cdot {V}_{ave - c} ( t - k ) + {c}_{2} \cdot \{ y ( t - k ) - y 0 \} \cdot {V}_{ave - c} ( t - 2 k ) + ⋯ + {c}_{n} \cdot \{ y ( t - k ) - y 0 \} \cdot {V}_{ave - c} ( t - nk ) + d \cdot \{ y ( t - k ) - y 0 \} \cdot \{ {f}_{ave} ( t - k ) + ⋯ + {f}_{ave} ( t - mk ) \} / m \qquad ( Equation 20 )$$

Here, for example,

$$[ Formula 36 ]$$

$${y}_{ave} ( t ) = \frac{{\sum }_{i = 1 - k}^{k - 1} y ( t - i )}{2 k - 1}$$

$$or$$

$${V}_{ave - a} ( t ) = \frac{{\sum }_{i = 0}^{k - 1} {V}_{a} ( t - i )}{k}$$

$${f}_{ave} ( t ) = \frac{{\sum }_{i = 0}^{k - 1} f ( t - i )}{k}$$

By using the above-described Equation 19 or Equation 20 as the rapid cooling prediction model, it is possible to acquire the predicted temperature with high accuracy even when the frequency component included in the characteristics is relatively small, and to reduce the amount of control operation.

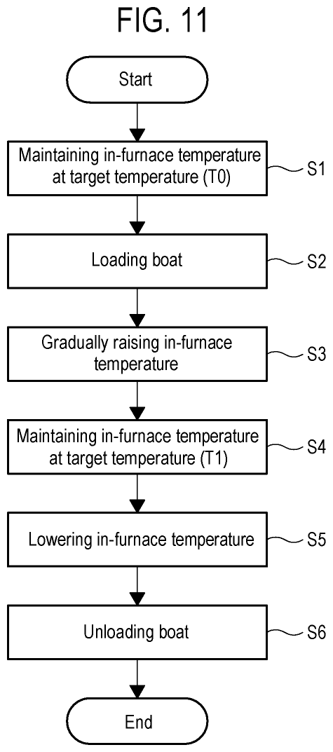

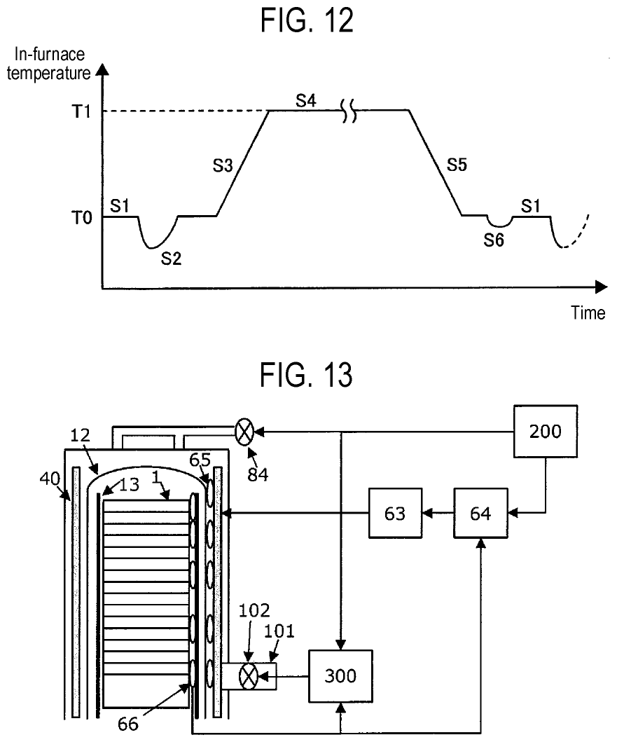

Next, an example of temperature sequence performed in the substrate processing apparatus 10 will be described with reference to FIGS. 11 to 13. Symbols S1 to S6 shown in FIG. 12 indicate that steps S1 to S6 of FIG. 11 are performed.

In step S1, the in-furnace temperature is maintained at a target temperature T0 which is lower than the processing temperature T1. The controller 200 inputs the target temperature to the temperature controller 64. The temperature controller 64 feeds back a temperature detected by the thermocouple 66 or the thermocouple 65 and, based on the target temperature input from the controller 200, controls a power supply value to a power supply circuit 63 such that the in-furnace temperature is controlled to maintain the target temperature TO. At this time, the wafer 1 is not loaded into the process chamber 14. From step S1 to step S4 to be described later, the controller 200 turns off the drive of the exhaust fan 84 and notifies the exhaust history storage 355 of the cooling controller 300 of information regarding an off signal of the exhaust fan 84. Further, from step S1 to step S4 to be described later, the temperature control by the cooling controller 300 is not performed, and the cooling valve 102 is closed.

In step S2, when a predetermined number of wafers 1 are charged in the boat 31, the boat 31 holding the group of wafers 1 is loaded into the process chamber 14 of the inner tube 13 (boat loading) as the seal cap 25 is lifted by the boat elevator 26. The seal cap 25 reaching its upper limit presses against the manifold 16 to seal the interior of the process tube 11. The boat 31 remains in the process chamber 14 while being supported by the seal cap 25. At this time, the temperatures of the boat 31 and the wafers 1 are lower than the in-furnace temperature TO, and as a result of inserting the wafers 1 held by the boat 31 into the furnace, an atmosphere (room temperature) outside the furnace is introduced into the furnace. Therefore, the in-furnace temperature temporarily becomes lower than TO, but is stabilized at T0 again after a short period of time due to the control by the temperature controller 64.

In step S3, the interior of the process tube 11 is exhausted via the exhaust pipe 18. Further, the temperature controller 64 performs sequence control to gradually raise the in-furnace temperature from the temperature T0 to the target temperature T1 at which a predetermined process is performed on the wafers 1. An error between the actual rising temperature of the interior of the process tube 11 and the target temperature of the sequence control of the temperature controller 64 is corrected by feedback control based on the measurement results of the thermocouples 65 and 66. Further, the boat 31 is rotated by a motor 29.

In step S4, when the internal pressure and temperature of the process tube 11 and the rotation of the boat 31 reach a constant and stable state as a whole, a precursor gas is introduced into the process chamber 14 of the process tube 11 from the gas introduction pipe 22 by the gas supplier 23. That is, the temperature controller 64 acquires the heater temperature or the in-furnace temperature and the power supply value at a predetermined control cycle and regulates the power supply value output to the heat generator 56 such that the in-furnace temperature is maintained and stabilized at the target temperature T1. The precursor gas introduced via the gas introduction pipe 22 flows through the interior of the process chamber 14 of the inner tube 13 and is exhausted via the exhaust pipe 18 via the exhaust passage 17. A predetermined film is formed on the wafer 1 by a thermal CVD reaction caused by contact of the precursor gas with the wafer 1 heated to a predetermined processing temperature while flowing through the process chamber 14.

After a predetermined processing time elapses, in step S5, after the introduction of the process gas is stopped, a purge gas such as a nitrogen gas is introduced into the process tube 11 via the gas introduction pipe 22. At the same time, a cooling gas 90 is supplied from the intake pipe 101 to the gas flow path 107 via the check damper 104. Then, the cooling gas 90 is ejected into the internal space 75 from the opening holes 110 as a plurality of cooling gas supply ports. Then, the cooling gas 90 ejected into the internal space 75 from the opening holes 110 is exhausted via the exhaust hole 81, the exhaust duct 82, and the exhaust fan 84.

In step S5, after the substrate processing is completed, the in-furnace temperature is quickly lowered (dropped) from the temperature T1 to the relatively low temperature T0 again. At this time, the controller 200 starts (turns on) driving the exhaust fan 84 and notifies the exhaust history storage 355 of the cooling controller 300 of information regarding an on signal of the exhaust fan 84. Then, the cooling controller 300 controls the opening state of the cooling valve 102 to obtain a desired temperature trajectory. At this time, the temperature control by the temperature controller 64 is not performed, and the supply power output to the heater structure 40 is set to zero. That is, the temperature controller 64 is configured to set the power supply value output to the heat generator 56 in each control zone to zero.

Since the entirety of heater structure 40 is forcibly cooled by the flow of the cooling gas 90 as described above, the heat insulation structure 42 is rapidly cooled at a high rate (speed) together with the process tube 11. Further, since the interior space 75 is isolated from the process chamber 14, the cooling gas 90 may be used. However, an inert gas such as a nitrogen gas may be used as the cooling gas to further enhance the cooling effect and to prevent the heat generator 56 from corroding under a high temperature due to impurities in the gas.

When the temperature of the process chamber 14 drops to the target temperature TO, in step S6, the boat 31 supported by the seal cap 25 is lowered by the boat elevator 26 to be unloaded from the process chamber 14 (boat unloading). At this time, the controller 200 turns off the drive of the exhaust fan 84 and notifies the exhaust history storage 355 of the cooling controller 300 of information regarding an off signal of the exhaust fan 84. Further, at this time, the temperature control by the cooling controller 300 is not performed, and the cooling valve 102 is closed.

Then, in a case where unprocessed wafers 1 to be processed remain, the processed wafers 1 on the boat 31 are replaced with the unprocessed wafers 1, and the series of steps S1 to S6 are performed.

The process of the above-described steps S1 to S6 obtains a stable state in which the in-furnace temperature is within a predetermined minute temperature range with respect to the target temperature and that condition continues for a predetermined time or longer, and then proceeds to the next step. Therefore, for example, quickly converging the in-furnace temperature to the target temperature T1 in the temperature raising step of step S3 is a control performance index.

Further, the in-furnace temperatures of a plurality of control zones may follow substantially the same temperature trajectory in these steps such that the same process is performed on the plurality of wafers 1 held in the boat 31. Therefore, reducing a value obtained by subtracting the minimum value from the maximum value of the in-furnace temperatures of the plurality of control zones (hereinafter, referred to as an inter-zone temperature deviation) is an control performance index.

With the cooling controller 300 according to the present disclosure, the inter-zone temperature deviation may be reduced. Further, even when there is a large variation in the individual temperature characteristics of heaters, or even when an engineer in charge does not obtain enough time, the thermal characteristics may be automatically acquired, and the optimal control method may be obtained without parameter regulation or with easy parameter regulation.

Therefore, the expected performance of the apparatus may be easily obtained. Further, with the cooling controller 300 according to the present disclosure, an inter-zone temperature error at the start of rapid cooling is improved by considering the influence of the exhaust of the in-furnace atmosphere due to the operation of the exhaust fan 84 for a minute time at the start of rapid cooling, thereby improving the temperature controllability.

### First Example

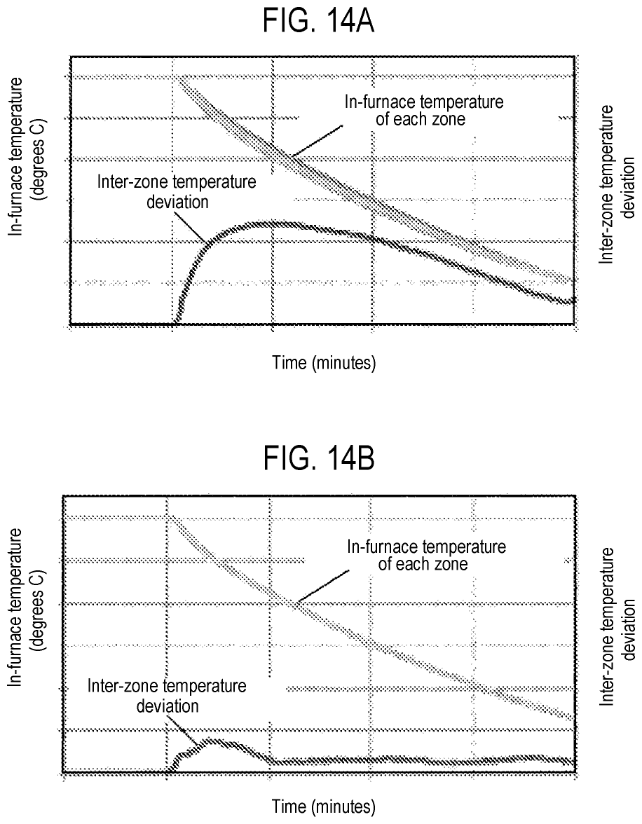

Next, a first example when the cooling controller 300 of the present disclosure is applied to the above-described temperature lowering step (step S5) will be described with reference to FIGS. 14A and 14B.

FIG. 14A is a diagram showing a in-furnace temperature trajectory of each zone when a cooling controller 300 according to a comparative example is applied to the above-described step S5 in FIG. 11. FIG. 14B is a diagram showing a in-furnace temperature trajectory of each zone when the cooling controller 300 according to the present example is applied to the above-described step S5 in FIG. 11. The cooling controller according to the comparative example controls the opening state of the cooling valve 102 such that a difference between a temperature detected by a thermocouple in a zone other than the reference zone and a temperature detected by a thermocouple in the reference zone becomes zero.

Comparing the inter-zone temperature deviation by the temperature control according to the comparative example shown in FIG. 14A and the inter-zone temperature deviation by the temperature control according to the present example shown in FIG. 14B, it is confirmed that the intern-zone temperature deviation may be reduced by performing the temperature control according to the present example. Further, in FIGS. 14A and 14B, the in-furnace temperatures of the L2 to U1 zones shown in FIG. 3 are actually compared.

### Second Example

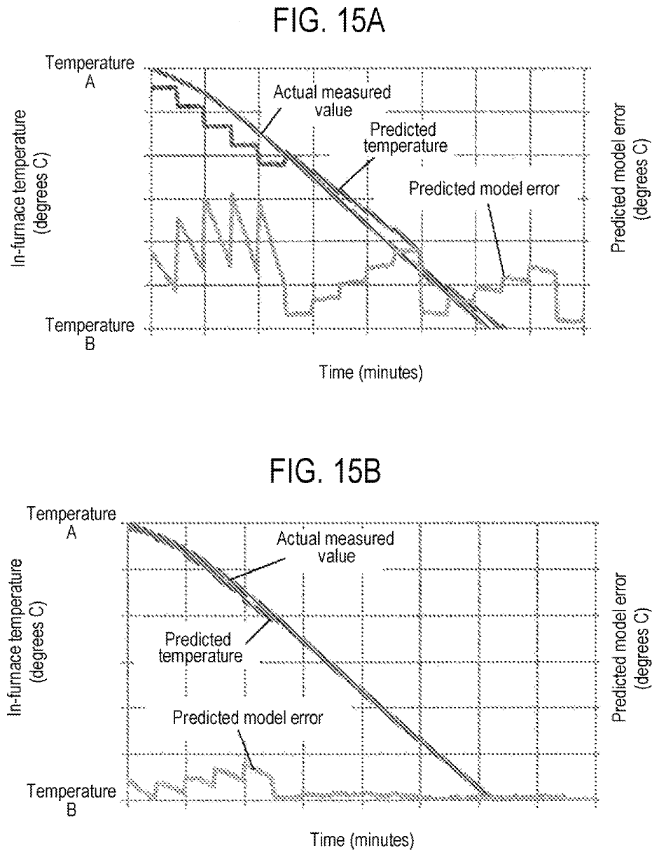

Next, a second example when the cooling controller 300 of the present disclosure is applied to the above-described temperature lowering step (step S5) in FIG. 11 will be described with reference to FIGS. 15A and 15B.

FIG. 15A a diagram showing an actual measured value of the in-furnace temperature, a predicted temperature, and a predicted model error as an error between the actual measured value and the predicted temperature when the temperature control, which uses the rapid cooling prediction model, is performed without using information of the exhaust fan 84 in the cooling controller 300 according to the present example. FIG. 15B is a diagram showing an actual measured value of the in-furnace temperature, a predicted temperature, and a predicted model error as an error between the actual measured value and the predicted temperature, when the temperature control is performed by using the cooling controller according to the present example.

As shown in FIGS. 15A and 15B, by performing the temperature control which uses the rapid cooling prediction model in which the information of the exhaust fan 84 is used, it is confirmed that the error between the actual measured value of rapid cooling and the predicted temperature is reduced and a predicted model error is reduced, as compared to the case where the temperature control is performed by using the rapid cooling prediction model without using the information of the exhaust fan 84. Specifically, it is confirmed that the predicted model error at the start of rapid cooling may be reduced, thereby improving the temperature controllability.

Although the embodiments of the present disclosure are specifically described above, the present disclosure is not limited to the above-described embodiments and examples, and may be modified in various forms without departing from the gist thereof.

Further, in the above-described embodiments, the temperature control, which uses the rapid cooling prediction model, is performed in step S5, but the temperature control in which the prediction model is used may be similarly performed in other steps. For example, in step S4, the temperature controller 64 may acquire the heater temperature or the in-furnace temperature and the power supply value at a predetermined control cycle, use the prediction model stored in the storage 205, and regulate the power supply value output to the heat generator 56 such that the deviation between the final target temperature and the predicted temperature is minimized, thereby maintaining and stabilizing the in-furnace temperature at the target temperature T1.

Further, in the above-described embodiments, the example in which the temperature controller 64 and the cooling controller 300 are separately provided is described, but the present disclosure is not limited thereto, and the temperature controller 64 and the cooling controller 300 may be combined into a single controller.

Further, in the above-described embodiments, the example in which a predetermined film is formed on the wafer 1 is described, but the film type is not particularly limited in the present disclosure. For example, the present disclosure may be suitably applied to a case of forming various types of films such as a nitride film (SiN film) and a metal oxide film on the wafer 1.

Further, the present disclosure may be applied to a LCD (Liquid Crystal Display) manufacturing apparatus configured to process a glass substrate, as well as a semiconductor manufacturing apparatus configured to process a semiconductor wafer, such as the substrate processing apparatus according to the above-described embodiments.

According to the present disclosure, it is possible to improve a temperature deviation among zones by using optimal parameters.

While certain embodiments are described above, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a reaction tube in which a process chamber configured to process a substrate is formed;
a heater structure that is installed outside the reaction tube and includes a heater configured to heat the substrate;
a cooler including a cooling valve configured to supply a cooling medium to a space between the heater structure and the reaction tube;
an exhaust fan configured to supply the cooling medium to the cooler; and
a cooling controller configured to: acquire a prediction model that includes information of the exhaust fan, a final target temperature that is a future target, and an opening state of the cooling valve and estimates a predicted temperature that predicts at least one selected from the group of a temperature of the heater and a temperature of the process chamber; acquire the at least one selected from the group of the temperature of the heater and the temperature of the process chamber, the opening state of the cooling valve, and the information of the exhaust fan; and regulate the opening state of the cooling valve to minimize an error between a predicted temperature column calculated according to the prediction model and a target temperature column calculated from a rate of change from a present target temperature to the final target temperature when the change occurs.

2. The substrate processing apparatus of claim 1, wherein the cooling controller includes a temperature history storage configured to store the at least one selected from the group of the temperature of the heater and the temperature of the process chamber, an exhaust history storage configured to store an on/off signal of the exhaust fan, and a valve opening state history storage configured to store opening state information to be output to the cooling valve, and
wherein the temperature history storage, the exhaust history storage, and the valve opening state history storage are configured to store data for a certain period of time respectively.

3. The substrate processing apparatus of claim 1, wherein the cooling controller further includes a creator configured to acquire the prediction model and acquire past temperature data of the at least one selected from the group of the temperature of the heater and the temperature of the process chamber, past on/off data of the exhaust fan, and past opening state data of the cooling valve, and calculate an individual input response characteristics matrix and an individual zero response characteristics vector.

4. The substrate processing apparatus of claim 1, wherein the prediction model is an equation that calculates the predicted temperature and is expressed by the following Equation 1:
$$[ Formula 1 ]$$
$$\hat{y} ( t ) = y ( t - 1 ) + {a}_{1} \cdot \{ y ( t - 1 ) - y 0 \} \cdot {V}_{a} ( t - 1 ) + {a}_{2} \cdot \{ y ( t - 1 ) - y 0 \} \cdot {V}_{a} ( t - 2 ) + ⋯ + {a}_{n} \cdot \{ y ( t - 1 ) - y 0 \} \cdot {V}_{a} ( t - n ) + {b}_{1} \cdot \{ y ( t - 1 ) - y 0 \} \cdot {V}_{b} ( t - 1 ) + {b}_{2} \cdot \{ y ( t - 1 ) - y 0 \} \cdot {V}_{b} ( t - 2 ) + ⋯ + {b}_{n} \cdot \{ y ( t - 1 ) - y 0 \} \cdot {V}_{b} ( t - n ) + {c}_{1} \cdot \{ y ( t - 1 ) - y 0 \} \cdot {V}_{c} ( t - 1 ) + {c}_{2} \cdot \{ y ( t - 1 ) - y 0 \} \cdot {V}_{c} ( t - 2 ) + ⋯ + {c}_{n} \cdot \{ y ( t - 1 ) - y 0 \} \cdot {V}_{c} ( t - n ) + d \cdot \{ y ( t - 1 ) - y 0 \} \cdot \{ f ( t - 1 ) + ⋯ + f ( t - m ) \} / m \qquad ( Equation 1 )$$
$$[ Formula 2 ]$$
wherein ŷ^{(t)} is the predicted temperature at time t, and y(t-1) is a temperature at one time before a present time,
Vₐ(t-1), Vₐ(t-2), . . . ,Vₐ(t-n) are opening states of relevant cooling zones at one time, two times, . . . , and n times before the present time,
V_{b}(t-1), V_{b}(t-2), . . . ,V_{b}(t-n) are opening states of zones adjacent to one side of the relevant cooling zones at one time, two times, . . . , n times before the present time,
V_{c}(t-1), V_{c}(t-2), . . . ,V_{c}(t-n) are opening states of zones adjacent to the other side of the relevant cooling zones at one time, two times, . . . , and n times before the present time,
f(t-1), f(t-2), . . . , f(t-m) are on/off data of the exhaust fan at one time, two times, . . . , and n times before the present time, and
y0 is a reference temperature, values n and m are arbitrary preset values, and a₁, . . . , aₙ, b₁, . . . , bₙ, c₁, . . . , cₙ, and d are predetermined coefficients.

5. The substrate processing apparatus of claim 4, wherein the reference temperature y0 is a temperature within a range of 20 degrees C. or higher and 30 degrees C. or lower, and
wherein the values n and m are the number of demanded past data.

6. The substrate processing apparatus of claim 3, wherein the creator is configured to create an equation expressed by the following Equation 3:
$$[ Formula 3 ]$$
$$\hat{y} ( t ) = {S}_{zr} + {S}_{sr} \cdot u ( t ) \qquad ( Equation 3 )$$
$$[ Formula 4 ]$$
$$\hat{y} ( t ) = [ \begin{matrix}\hat{y} ( t + 1 ) \\ \hat{y} ( t + 2 ) \\ \hat{y} ( t + 3 ) \\ ⋮\end{matrix} ] ,$$
$${S}_{zr} = [ \begin{matrix}C \cdot {A}^{2} \\ C \cdot {A}^{3} \\ C \cdot {A}^{4} \\ ⋮\end{matrix} ] \cdot x ( t - 1 ) + [ \begin{matrix}C \cdot A \cdot B \\ C \cdot {A}^{2} \cdot B \\ C \cdot {A}^{3} \cdot B \\ ⋮\end{matrix} ] \cdot u ( t - 1 ) ,$$
$${S}_{sr} = [ \begin{matrix}C \cdot B \\ {\sum }_{i = 0}^{1} C \cdot {A}^{i} \cdot B \\ {\sum }_{i = 0}^{2} C \cdot {A}^{i} \cdot B \\ ⋮\end{matrix} ]$$
and
wherein S_{zr} in Equation 3 is an individual zero response characteristics vector, Sₛᵣ is an individual input response characteristics matrix, and ŷ(t) is a predicted temperature vector.

7. The substrate processing apparatus of claim 6, wherein the individual zero response characteristics vector S_{zr} indicates an amount of change in the predicted temperature vector that changes under an influence by the past temperature and past opening state, and the individual input response characteristics matrix Sₛᵣ indicates an amount of change in the predicted temperature vector that changes under an influence by the opening state calculated at a present time.

8. The substrate processing apparatus of claim 6, wherein the cooling controller further includes a target temperature column creator configured to calculate an individual target temperature column vector S_{tg} shown by the following Equation 4,
wherein the target temperature column creator is configured to calculate the individual target temperature column vector S_{tg} from a target temperature, the present target temperature, and the rate of change from the present target temperature to the final target temperature when the change occurs:
$$[ Formula 5 ]$$
$${S}_{tg} ( t ) = [ \begin{matrix}{S}_{tg} ( t + 1 ) \\ {S}_{tg} ( t + 2 ) \\ {S}_{tg} ( t + 3 ) \\ ⋮\end{matrix} ] , \qquad ( Equation 4 )$$
and
wherein time t and the number of rows in Equation 4 correspond to the time (t) and the number of rows in Equation 3.

9. The substrate processing apparatus of claim 8, wherein the target temperature column creator calculates a ramping temperature deviation between the target temperature and the present target temperature and divides an absolute value of the ramping temperature deviation by the rate of change,
wherein when the rate of change is zero, the target temperature column creator calculates a reference set value by the following formula:
Reference set value=present target temperature+ramping temperature deviation×(1-exp(elapsed time÷(ramping time÷time constant))),
wherein when the rate of change is other than zero, the target temperature column creator calculates the reference set value by the following formula:
Reference set value=present target temperature+ramping temperature deviation×(1-exp(elapsed time÷ramping time)), and
wherein the target temperature column creator calculate the individual target temperature column vector S_{tg} according to the reference set value.

10. The substrate processing apparatus of claim 8, wherein the cooling controller further includes an integrated characteristics creator configured to create a predetermined equation from the individual input response characteristics matrix Sₛᵣ, the individual zero response characteristics vector S_{zr}, and the individual target temperature column vector S_{tg}, and
wherein the integrated characteristics creator is configured to transform the individual input response characteristics matrix Sₛᵣ into an individual input response characteristics matrix S_{dsr} expressed by the following equation:
$$[ Formula 6 ]$$
$${S}_{dsr} = [ \begin{matrix}C \cdot B \\ C \cdot A \cdot B + C \cdot B \\ {\sum }_{i = 0}^{2} C \cdot {A}^{t} \cdot B \\ ⋮ \\ {\sum }_{i = 0}^{Np - 1} C \cdot {A}^{t} \cdot B\end{matrix} ] .$$

11. The substrate processing apparatus of claim 10, wherein the integrated characteristics creator is configured to arrange the individual zero response characteristics vector S_{zr}, the individual input response characteristics matrix S_{dsr}, and the individual target temperature column vector S_{tg} in an entirety of cooling zones to be controlled, respectively, and create a predicted temperature column including an integrated input response characteristics matrix U_{dsr} and an integrated zero response characteristics vector U_{zr} and a target temperature column including an integrated target temperature vector U_{tg}, respectively.

12. The substrate processing apparatus of claim 11, wherein the cooling controller further includes a calculator configured to create an evaluation function indicating a square of the error between the target temperature column and the predicted temperature column, and calculate a predetermined simultaneous equation to minimize the evaluation function, and
wherein the calculator is configured to acquire the opening state of the cooling valve included in a solution of the predicted temperature column by solving the predetermined simultaneous equation.

13. The substrate processing apparatus of claim 12, wherein the cooling controller is configured to include an opening state signal supplier configured to update the opening state of the cooling valve, which is acquired from the calculator, in a predetermined control cycle.

14. The substrate processing apparatus of claim 1, wherein the heater structure is divided into a plurality of control zones, and is provided with a temperature sensor configured to detect a temperature of each of the control zones, and
wherein the cooler is divided into a plurality of cooling zones, each of which being provided with the cooling valve.

15. The substrate processing apparatus of claim 14, wherein the prediction model is configured to predict a predicted temperature of the at least one selected from the group of the temperature of the heater in each of the cooling zones and the temperature of the process chamber and corresponds to each temperature zone.

16. A non-transitory computer-readable recording medium storing a temperature control program that is executed in a substrate processing apparatus including:
a reaction tube in which a process chamber configured to process a substrate is formed;
a heater structure that is installed outside the reaction tube and includes a heater configured to heat the substrate;
a cooler including a cooling valve configured to supply a cooling medium to a space between the heater structure and the reaction tube; and
an exhaust fan configured to supply the cooling medium to the cooler,
wherein the temperature control program that causes, by a computer, the substrate processing apparatus to perform a process comprising:
acquiring a prediction model that includes information of the exhaust fan, a final target temperature that is a future target, and an opening state of the cooling valve and estimates a predicted temperature that predicts at least one selected from the group of a temperature of the heater and a temperature of the process chamber;
acquiring the at least one selected from the group of the temperature of the heater and the temperature of the process chamber, a temperature ratio, the opening state of the cooling valve, and the information of the exhaust fan; and
regulating the opening state of the cooling valve to minimize an error between a predicted temperature column calculated according to the prediction model and a target temperature column calculated from a rate of change from a present target temperature to the final target temperature when the change occurs.

17. A method of manufacturing a semiconductor device, comprising:
raising a temperature of a process chamber configured to process a substrate, from a predetermined temperature to a processing temperature;
processing the substrate while maintaining the processing temperature; and
lowering the temperature of the process chamber from the processing temperature after processing the substrate,
wherein the act of lowering the temperature of the process chamber includes:
acquiring at least one selected from the group of a temperature of a heater and the temperature of the process chamber, an opening state of a cooling valve, and information of an exhaust fan; and
regulating the opening state of the cooling valve to minimize an error between a predicted temperature column calculated according to a prediction model that includes the information of the exhaust fan, a final target temperature that is a future target, and the opening state of the cooling valve and estimates a predicted temperature that predicts the at least one selected from the group of the temperature of the heater and the temperature of the process chamber, and a target temperature column calculated from a rate of change from a present target temperature to the final target temperature when the change occurs.

18. The method of claim 17, wherein the act of lowering the temperature of the process chamber includes setting a power supply value output from the heater to zero.
